(19) United States
(12) Patent Application Publication
(10) Pub. No.: US 2025/0176412 A1
(43) Pub. Date: May 29, 2025

(54) DISPLAY DEVICE WITH IMPROVED LIGHT EXTRACTION AND EMISSION EFFICIENCY

(71) Applicant: LG DISPLAY CO., LTD., Seoul (KR)

(72) Inventors: Howon CHOI, Paju-si (KR); KyungMin KIM, Paju-si (KR)

(73) Assignee: LG DISPLAY CO., LTD., Seoul (KR)

(21) Appl. No.: 18/914,805

(22) Filed: Oct. 14, 2024

(30) Foreign Application Priority Data
Nov. 28, 2023 (KR) 10-2023-0168259

(51) Int. Cl. H10K 59/80; H10K 59/122

(52) U.S. Cl. CPC H10K 59/878; H10K 59/122; H10K 59/80518

(57) ABSTRACT

In one aspect, a display panel includes a plurality of sub-pixels, each of the plurality of sub-pixels including a substrate; a first insulating layer on the substrate protruding away from the substrate, the first insulating layer having two side surfaces; and a light emitting device on the first insulating layer having a first electrode, a second electrode, and a light emitting layer, the first electrode at least partially covering the first insulating layer, wherein the second electrode is on the two side surfaces.

### CROSS-REFERENCE TO RELATED APPLICATIONS

This application claims the benefit of the Korean Patent Application No. 10-2023-0168259 filed on Nov. 28, 2023, which is hereby incorporated by reference as if fully set forth herein.

### BACKGROUND

### Field of Disclosure

The present disclosure relates to a display device having a bottom emission structure.

### Description of Background

Display devices may be categorized into a bottom emission structure and a top emission structure depending on the direction in which the emitted light is emitted. A display device with the bottom emission structure may emit the emitted light downward, while a display device with the top emission structure may emit the emitted light upward.

In display devices with the bottom emission structure, research is being conducted to improve light extraction efficiency by utilizing the structure of the layers disposed below the light emitting device.

### SUMMARY

The present disclosure is directed to providing a display device that substantially obviates one or more problems due to limitations and disadvantages of the related art.

An aspect of the present disclosure is directed to providing a display device that is capable of improving aperture and light extraction efficiency.

Another aspect of the present disclosure is directed to providing a display device capable of preventing light leakage defects.

Another aspect of the present disclosure is directed to providing a display device that may have a high light emitting efficiency with low power.

Another aspect of the present disclosure is directed to a method of manufacturing a display panel that is capable of improving aperture and light extraction efficiency, prevents light leakage defects, and/or has high light emitting efficiency with low power.

In one aspect, a display panel includes a plurality of sub-pixels, each of the plurality of sub-pixels including a substrate; a first insulating layer on the substrate protruding away from the substrate, the first insulating layer having two side surfaces; and a light emitting device on the first insulating layer having a first electrode, a second electrode, and a light emitting layer, the first electrode at least partially covering the first insulating layer, wherein the second electrode is on the two side surfaces.

In another aspect, the display panel further includes a reflective layer including a first layer on the first electrode and a second layer on the first layer, the first layer being formed of reflective material and the second layer being formed of transparent material.

In another aspect, a thickness of the second layer is smaller than a thickness of the first electrode.

In another aspect, the display panel further includes a second insulating layer, wherein the first insulating layer has a first refractive index and the second insulating layer has a second refractive index.

In another aspect, the first refractive index is greater than the second refractive index.

In another aspect, the display panel further includes a circuit element layer including a plurality of metal patterns.

In another aspect, the display panel further includes a color filter on the circuit element layer covering the plurality of metal patterns.

In another aspect, the color filter corresponds to an emission area of a corresponding one of the plurality of sub-pixels.

In another aspect, the two side surfaces are inclined.

In another aspect, the first layer contacts and covers the two side surfaces while partially covering a top surface of the first insulating layer.

In another aspect, the light emitting layer has a multi-layer structure.

In another aspect, the first electrode extends horizontally beyond the two side surfaces and partially covering a top surface of a second insulating layer, the first insulating layer being on the second insulating layer.

In another aspect, the plurality of metal patterns are in a non-emission area between two adjacent ones of the plurality of sub-pixels and do not overlap with the first insulating layer and the first electrode.

In another aspect, the first insulating layer is on a second insulating layer, the second insulating layer extending beyond a horizontal length of the first insulating layer to cover non-emission areas between adjacent ones of the plurality of sub-pixels.

In another aspect, the second insulating layer has a first height from a top surface of the substrate in a first region and a second height from the top surface of the substrate in a second region.

In another aspect, the first region is where the second insulating layer contacts the first insulating layer and the second region is where the second insulating layer covers the non-emission areas.

In another aspect, the first electrode is horizontally disposed on a top surface of the first insulating layer.

In another aspect, the display panel further includes a bank layer disposed between the first layer and each of the two side surfaces.

In another aspect, the first layer covers the bank layer and a portion of the first electrode.

In another aspect, the first layer contacts the portion of the first electrode through the bank layer via a contact hole.

In another aspect, each of the plurality of sub-pixels has an emission area including a first emission area and two side emission areas, the two side emission areas corresponding to the two side surfaces.

In another aspect, light is directly emitted in the first emission area.

In another aspect, the light is emitted both directly and via reflection in the two side emission areas.

Additional advantages and features of the disclosure will be set forth in part in the description which follows and in part will become apparent to those having ordinary skill in the art upon examination of the following or may be learned from practice of the disclosure. Other benefits of the disclosure may be realized and attained by the structure particularly pointed out in the written description and claims hereof as well as the appended drawings.

It is to be understood that both the foregoing general description and the following detailed description of the present disclosure are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 illustrates a display device according to one or more aspects of the present disclosure;

FIG. 2 is a block diagram schematically illustrating of the configuration of a display device according to one or more aspects of the present disclosure;

FIG. 3 is a plan view illustrating one example of a pixel provided in a display device according to one or more aspects of the present disclosure;

FIG. 4 is a circuit diagram illustrating one example of a sub-pixel shown in FIG. 3 according to one or more aspects of the present disclosure;

FIG. 5 is cross-sectional view illustrating a first example of a sub-pixel taken along line I-I′ of FIG. 3 according to one or more aspects of the present disclosure;

FIG. 6 is a plan view illustrating one example of a first electrode and a reflective layer according to one or more aspects of the present disclosure;

FIG. 7 is a cross-sectional view illustrating one example of a light path according to one or more aspects of the present disclosure;

FIG. 8 is a cross-sectional view illustrating a modified example of the sub-pixel shown in FIG. 5 according to one or more aspects of the present disclosure;

FIG. 9 is a cross-sectional view illustrating a second example of the sub-pixel taken along line to I-I′ shown in FIG. 3 according to one or more aspects of the present disclosure;

FIG. 10 is a cross-sectional view illustrating a modified example of the sub-pixel shown in FIG. 9 according to one or more aspects of the present disclosure;

FIG. 11 is a cross-sectional view illustrating a third example of the sub-pixel taken along line I-I′ shown in FIG. 3 according to one or more aspects of the present disclosure;

FIG. 12 is a cross-sectional view illustrating a fourth example of the sub-pixel taken along line I-I′ shown in FIG. 3 according to one or more aspects of the present disclosure;

FIG. 13 is a flow chart illustrating a method of manufacturing a display panel according to one or more aspects of the present disclosure;

FIGS. 14A to 14F are cross-sectional views illustrating a method of manufacturing a display panel according to one or more aspects of the present disclosure;

FIG. 15 is a flow chart illustrating a method of manufacturing a display panel according to one or more aspects of the present disclosure; and

FIGS. 16A to 16H are cross-sectional views illustrating a method of manufacturing a display panel according to one or more aspects of the present disclosure.

### DETAILED DESCRIPTION

Advantages and features of the present disclosure, and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art. Furthermore, the present disclosure is only defined by scopes of claims.

A shape, a size, a ratio, an angle, and a number disclosed in the drawings for describing embodiments of the present disclosure are merely an example, and thus the present disclosure is not limited to the illustrated details. Like reference numerals refer to like elements throughout. In the following description, when the detailed description of the relevant known technology is determined to unnecessarily obscure the important point of the present disclosure, the detailed description will be omitted. In a case where ‘comprise,’ ‘have,’ and ‘include’ described in the present disclosure are used, another part may be added unless ‘only˜’ is used. The terms of a singular form may include plural forms unless referred to the contrary.

In construing an element, the element is construed as including an error range although there is no explicit description.

In describing a positional relationship, for example, when a position relation between two parts is described as ‘on˜’, ‘over˜’, ‘under˜’, and ‘next˜’, one or more other parts may be disposed between the two parts unless ‘just’ or ‘direct’ is used.

It will be understood that, although the terms “first,” “second,” etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

The term “at least one” should be understood as including any and all combinations of one or more of the associated listed items. For example, the meaning of “at least one of a first item, a second item, and a third item” denotes the combination of all items proposed from two or more of the first item, the second item, and the third item as well as the first item, the second item, or the third item.

Features of various embodiments of the present disclosure may be partially or totally coupled to or combined with each other, and may be variously inter-operated and driven technically. The embodiments of the present disclosure may be carried out independently from each other or may be carried out together with a co-dependent relationship.

Hereinafter, with reference to the accompanying drawings, one example of a display device according to the present disclosure is described. In assigning reference numerals to the components in each drawing, the same component may have the same numeral as far as possible, even if it is shown in different drawings. In addition, when the detailed description of the relevant known technology is determined to unnecessarily obscure the important point of the present disclosure, the detailed description will be omitted.

Hereinafter, with reference to the accompanying drawings, one or more embodiments of a display device according to the present disclosure will be described.

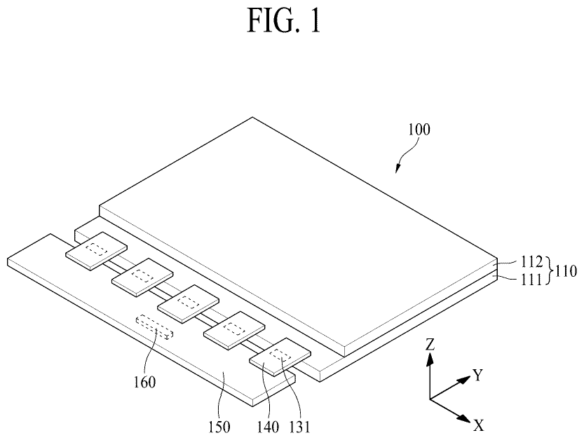

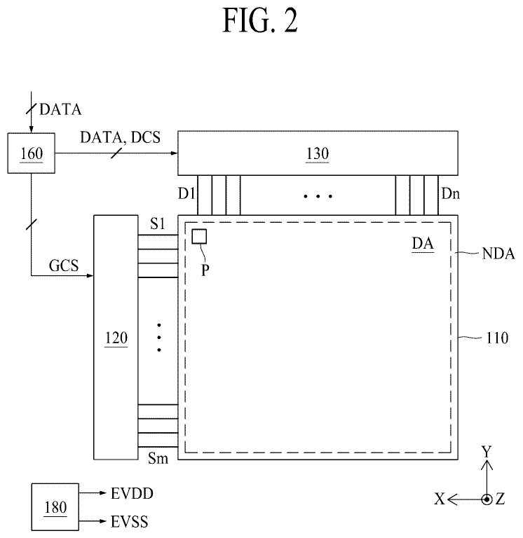

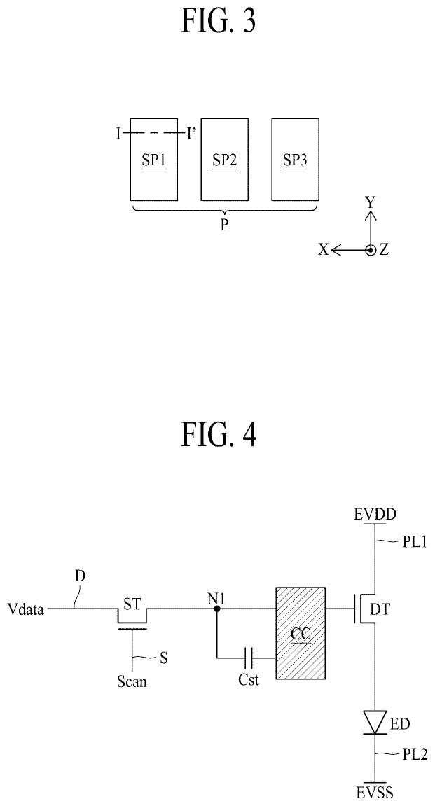

FIG. 1 illustrates a display device according to one or more aspects of the present disclosure, FIG. 2 is a block diagram schematically illustrating of the configuration of a display device according to one or more aspects of the present disclosure, and FIG. 3 is a plan view illustrating one example of a pixel provided in a display device according to one or more aspects of the present disclosure.

Although the display device 100 according to one or more aspects of the present disclosure is mainly described as an organic light emitting display apparatus, the display device 100 may, alternatively, be implemented as a liquid crystal display (LCD) apparatus, a quantum dot light emitting display (OLED) apparatus, and/or an electrophoresis display apparatus.

Referring to FIGS. 1 and 2, the display device 100 according to one or more aspects of the present disclosure may include a display panel 110, a scan driver 120 embedded in the display panel 110, a data driver 130 coupled to the display panel 110, a timing controller 160 controlling the scan driver 120 and the data driver 130, and a power circuit 180.

The display panel 110 includes a first substrate 111 and a second substrate 112. The second substrate 112 may be an encapsulation substrate. The first substrate 111 may include, but is not necessarily limited thereto, a plastic film or a glass substrate. The first substrate 111 may include a semiconductor material, such as a silicon wafer. The second substrate 112 may include a plastic film, a glass substrate, or an encapsulation film (protective film).

The display device 100 according to one aspect of the present disclosure may be configured in a bottom emission manner in which the emitted light is emitted downward. In this case, the first substrate 111 may include a transparent material, and the second substrate 112 may include an opaque material as well as a transparent material.

The display panel 110 includes a display area DA and a non-display area NDA outside of the display area DA. The display panel 110 can display images through pixels P disposed on the display area DA. The pixels P may include two or more sub-pixels SP. In one example, the pixel P may include a plurality of sub-pixels SP1, SP2, and SP3 as shown in FIG. 3. The plurality of subpixels SP1, SP2, and SP3 may include, but are not necessarily limited thereto, a first subpixel SP1 emitting red light, a second subpixel SP2 emitting green light, and a third subpixel SP3 emitting blue light. The plurality of sub-pixels SP1, SP2, and SP3 may further comprise a fourth sub-pixel emitting white light. Further, the arrangement order of the sub-pixels SP1, SP2, and SP3 may be varied.

Data lines D1 to Dn (where n is a positive integer greater than or equal to 2) and scan lines SI to Sm (where m is a positive integer greater than or equal to 2) connecting the sub-pixels SP1, SP2, and SP3 are disposed on the display panel 110. The data lines D1 to Dn may be disposed to intersect the scan lines SI to Sm. Each of the sub-pixels SP1, SP2, and SP3 of the display panel 110 may be connected to any one of the data lines D1 to Dn and any one of the scan lines SI to Sm. The data lines D1 to Dn may supply a data voltage supplied from the data driver 130 to each of the sub-pixels SP1, SP2, and SP3. The scan lines SI to Sm may supply a scan signal supplied from the scan driver 120 to each of the sub-pixels SP1, SP2, and SP3.

Each of the sub-pixels SP1, SP2, and SP3 may be turned on by the scan signal, and when the data voltage of the data lines D1 to Dn is supplied to the gate electrode of a driving transistor, the light emitting device may emit according to the drain-to-source current of the driving transistor.

The scan driver 120 may receive a scan control signal GCS from the timing controller 160. The scan driver 120 may supply scan signals or light emission control signals to the scan lines SI to Sm using the scan control signal GCS.

The scan driver 120 may be disposed in a gate driver in panel GIP manner on the non-display area NDA outside one side or both sides of the display area DA. Alternatively, the scan driver 120 may be fabricated as a driving chip type, mounted on a flexible film, and attached to the non-display area NDA on the outside of one side or both sides of the display area DA by tape automated bonding TAB.

The data driver 130 may receive digital video data DATA and data control signal DCS from the timing controller 160. The data driver 130 may convert the digital video data DATA to analog positive/negative data voltage using the data control signal DCS and supply them to the data lines D1 to Dn.

The data driver 130 may include a plurality of data drive ICs 131 as shown in FIG. 1. Each of the plurality of data drive ICs 131 may be mounted on a circuit film 140 in a chip on film COF manner, chip on plastic COP manner, flexible printed circuit (FPC) manner, or flexible flat cable (FFC) manner. The circuit film 140 may be attached to pads disposed on the non-display area NDA of the display panel 110 using anisotropic conducting film, and thus, the plurality of data drive ICs may be connected to the pads.

The circuit board 150 may be attached to the circuit film 140. A plurality of circuits implemented as driving chips may be mounted on the circuit board 150. For example, the timing controller 160 may be mounted on the circuit board 150. The circuit board 150 may be a printed circuit board PCB or a flexible printed circuit board FPCB.

The timing controller 160 may receive the digital video data DATA and the timing signals from the host system. The timing signals may include a vertical synchronization signal, a horizontal synchronization signal, a data enable signal, a dot clock, and the like. The vertical synchronization signal defines the duration of one frame. The horizontal synchronization signal defines the one horizontal period required to supply data voltages to the pixels of one horizontal line of the display panel 110. The data enable signal defines the period during which valid data is input. The dot clock is a signal that repeats at a predetermined short interval.

Based on the timing signals, the timing controller 160 generates the data control signal DCS to control the timing of operation of the data driver 130 and the scan control signal GCS to control the timing of operation of the scan driver 120. The timing controller 160 outputs the scan control signal GCS to the scan driver 120, and outputs the digital video data DATA and the data control signal DCS to the data driver 130.

The power circuit 180 may generate and supply a plurality of driving voltages required for operation of all circuit configurations of the display device 100 using an input voltage. The power circuit 180 may generate and supply a first power voltage EVDD, a second power voltage EVSS, and an initialization voltage Vref (reference voltage) to the display panel 110. The power circuit 180 may generate and supply various driving voltages required for operation of the scan driver 120, data driver 130, and timing controller 160.

FIG. 4 is a circuit diagram illustrating one example of a sub-pixel shown in FIG. 3 according to one or more aspects of the present disclosure.

Referring to FIGS. 3 and 4, each sub-pixel SP1, SP2, and SP3 may have a 2T (Transistor) 1C (Capacitor) structure including two transistors DT and ST and one capacitor Cst. However, the structure of SP1, SP2, and SP3 is not limited thereto. Each of the sub-pixels SP1, SP2, and SP3 may further include a compensation circuit CC. In this case, each sub-pixel SP1, SP2, and SP3 may have various structures, such as 3T1C, 4T2C, 5T2C, 6T1C, 6T2C, 7T1C, 7T2C, etc.

Each of the transistors DT and ST of each of the sub-pixels SP1, SP2, and SP3 includes a gate electrode, a source electrode, and a drain electrode. Since the positions of the source electrode and the drain electrode are not fixed and may be changed depending on the direction of the voltage and current applied to the gate electrode, one of the source electrode and the drain electrode may be represented as the first electrode and the other may be represented as the second electrode. The transistors DT and ST of each sub-pixel SP1, SP2, and SP3 may use at least one of a polysilicon semiconductor, an amorphous silicon semiconductor, and an oxide semiconductor. The transistors DT and ST may be P-type or N-type, or a combination of P-type and N-type.

The light emitting device ED may include an anode electrode connected to the driving transistor DT, a cathode electrode supplied with the second power voltage EVSS from a second power line PL2, and a light emitting layer between the anode electrode and the cathode electrode. The anode electrode may be disposed independently for each light emitting device, but the cathode electrode may be shared by all light emitting devices. When a driving current is supplied from the driving transistor DT, electrons from the cathode electrode are injected into the light emitting layer and holes from the anode electrode are injected into the light emitting layer, and the fluorescent or phosphorescent materials may be emitted by the recombination of electrons and holes in the light emitting layer, so that the light emitting device ED may generate light with a brightness proportional to the current value of the driving current.

In each sub-pixel SP1, SP2, and SP3, a driving transistor DT is connected between the anode electrode of the light emitting device ED and a first power line PL1 supplying the first power voltage EVDD. Here, the first power voltage EVDD is applied to the first electrode of the driving transistor DT.

The above driving transistor DT is for driving the light emitting device ED and is controlled by the voltage applied to the gate electrode to supply current to the light emitting device ED. Accordingly, the light emitting device ED is driven.

In each of the sub-pixels SP1, SP2, and SP3, a switching transistor ST is connected between a first node N1 and the data line D. The switching transistor ST is controlled by the scan signal Scan supplied from the scan line S and applies the data voltage Vdata supplied from the data line D to the first node N1.

In each of the sub-pixels SP1, SP2, and SP3, a capacitor Cst is connected to the first node N1 to charge the voltage applied to the first node N1. The capacitor Cst may supply the charged driving voltage to the driving transistor DT. The capacitor Cst is a storage capacitor.

The compensation circuit CC may be disposed to compensate for a threshold voltage of the driving transistor DT. The compensation circuit CC may comprise one or more transistors. The compensation circuitry CC may include one or more transistors and capacitors, and may be configured in various ways depending on the compensation method. The pixel including the compensation circuit CC may have various structures, such as 3T1C, 4T2C, 5T2C, 6T1C, 6T2C, 7T1C, 7T2C, etc.

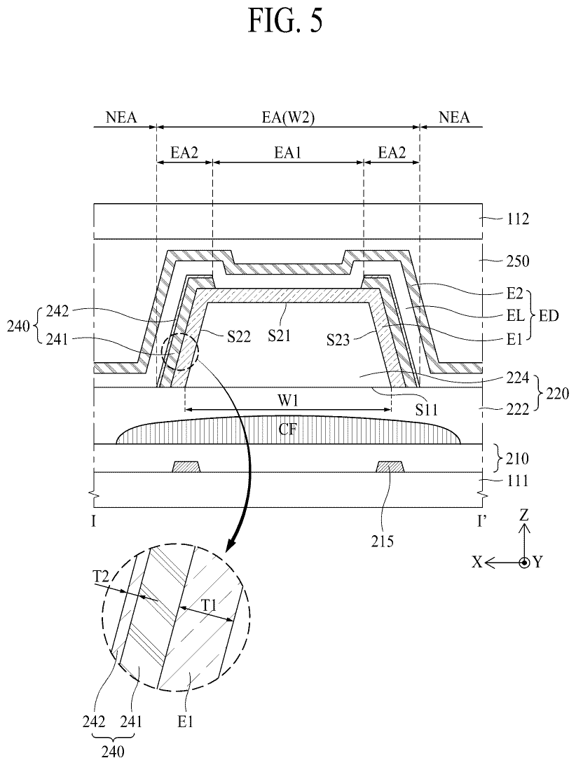

The display device 100 according to one aspect of the present disclosure may have a bottom emission structure in which light emitted from the light emitting device ED is emitted downward. The display device 100 according to one aspect of the present disclosure may modify the structure of the layers disposed below the light emitting device ED to improve the extraction efficiency of the light emitted from the light emitting device ED. Hereinafter, with reference to FIGS. 5 to 12, a structure for improving the light extraction efficiency will be described in more detail.

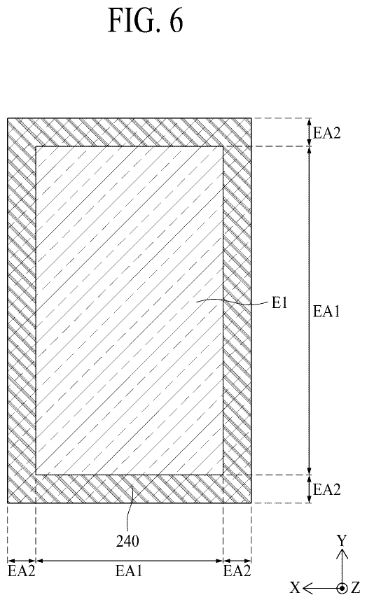

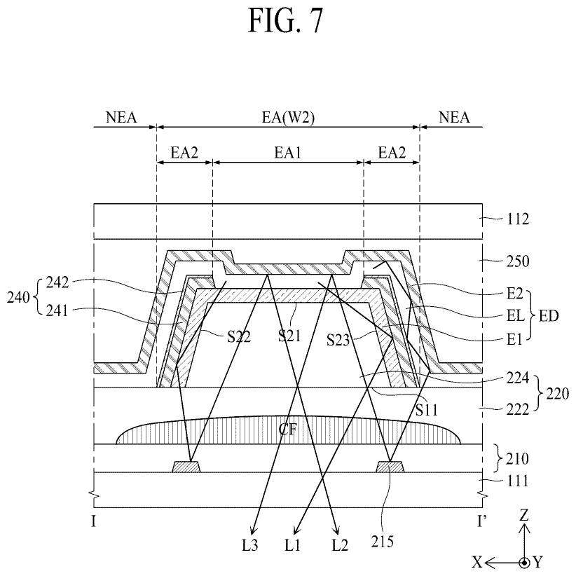

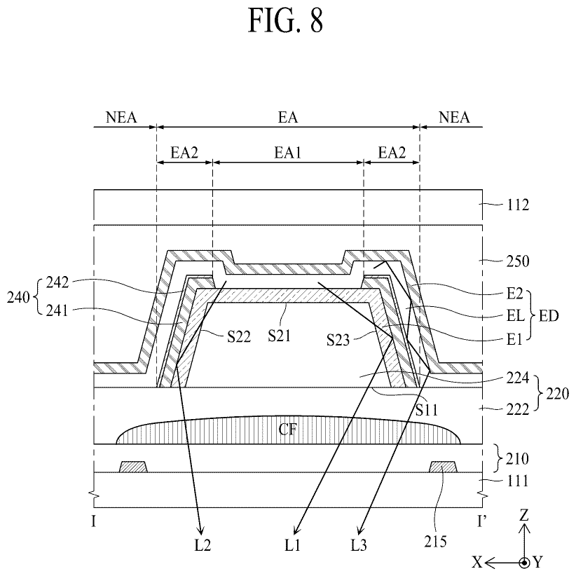

FIG. 5 is cross-sectional view illustrating a first example of a sub-pixel taken along line I-I′ of FIG. 3 according to one or more aspects of the present disclosure, FIG. 6 is a plan view illustrating one example of a first electrode and reflective layer according to one or more aspects of the present disclosure, FIG. 7 is a cross-sectional view illustrating one example of a light path according to one or more aspects of the present disclosure, and FIG. 8 is a cross-sectional view illustrating a modified example of the sub-pixel shown in FIG. 5 according to one or more aspects of the present disclosure.

Referring to FIG. 5, the display panel 110 according to a first aspect of the present disclosure includes a first substrate 111 and a second substrate 112 facing each other. A circuit element layer 210, a color filter CF, an insulating layer 220, a light emitting device ED, a reflective layer 240, and an encapsulation layer 250 may be disposed between the first substrate 111 and the second substrate 112.

The circuit element layer 210 may include circuit elements including various signal lines, thin film transistors, and capacitors for each of the sub-pixels SP1, SP2, and SP3. The signal lines may include scan lines, data lines, power lines, and the like. The thin film transistors may include switching transistor, driving transistor, and the like. The circuit element layer 210 may further include a plurality of insulating layers stacked on the first substrate 111.

The circuit element layer 210 may include a plurality of metal patterns 215. Each of the plurality of metal patterns 215 may be a component of a circuit element including various signal lines, thin film transistors, capacitors, and the like. In FIG. 5, a plurality of metal patterns 215 are shown as being disposed on the same layer, but it is not necessarily limited thereto. Each of the plurality of metal patterns 215 may be disposed on one of the layers disposed between the first substrate 111 and the insulating layer 220, and does not necessarily need to be disposed on the same layer. Some of the plurality of metal patterns 215 may be disposed on the same layer, and other portions may be provided on different layers with some of the plurality of insulating layers interposed therebetween. For example, some of the plurality of metal patterns 215 may be signal lines disposed directly on the first substrate 111. As another example, some of the plurality of metal patterns 215 may be signal lines disposed on a buffer layer (not shown) formed on the first substrate 111.

The plurality of metal patterns 215 may include a conductive material having reflectivity. The plurality of metal patterns 215 may include metals such as aluminum Al, silver Ag, titanium Ti, and silver-palladium-copper APC alloys.

The color filter CF may be disposed on the circuit element layer 210. The color filter CF may be patterned per sub-pixel SP1, SP2, and SP3. Specifically, the color filter CF may include a first color filter, a second color filter, and a third color filter. The first color filter may be disposed to correspond to the emission area EA of the first sub-pixel SP1. For example, the first color filter may be a red color filter that transmits red light. The second color filter may be disposed to correspond to the emission area EA of the second sub-pixel SP2, and may be a green color filter that transmits green light. The third color filter may be disposed to correspond to the emission area EA of the third sub-pixel SP3, and may be a blue color filter that transmits blue light. When the pixel further comprises a fourth sub-pixel, the color filter CF may further comprise a fourth color filter. The fourth color filter may be disposed to correspond to the emission area EA of the fourth sub-pixel, and may be a white color filter that transmits white light. The white color filter may include, but is not necessarily limited thereto, a transparent organic material that transmits white light. The white color filter may be omitted.

The first to third color filters CF1, CF2, and CF3 may overlap at least partially in the region between the sub-pixels SP1, SP2, and SP3, but are not necessarily limited thereto. The first to third color filters CF1, CF2, and CF3 may also be spaced apart in the region between the sub-pixels SP1, SP2, and SP3.

The insulating layer 220 may be disposed on the color filter CF. The insulating layer 220 may include two insulating layers such as a first insulating layer 222 and a second insulating layer 224 with different refractive indices to improve the extraction efficiency of light emitted from the light emitting device ED.

The first insulating layer 222 is disposed on the color filter CF and may have a first refractive index. The second insulating layer 224 is disposed on the first insulating layer 222 and may have a second refractive index. In one example, the second refractive index may be greater than the first refractive index. The second insulating layer 224 may also be referred to as the second insulating pattern 224.

Since the second refractive index of the second insulating layer 224 is greater than the first refractive index of the first insulating layer 222, light emitted from the light emitting device ED may be refracted or reflected at the interface of the second insulating layer 224 and the first insulating layer 222 to change a light path. The light extraction efficiency of the display panel 110 according to the first aspect of the present disclosure may be improved by the changed light path.

The first insulating layer 222 may be disposed on the color filter CF to cover the color filter CF. The first insulating layer 222 may planarize the steps caused by the color filters CF disposed on each of the sub-pixels SP1, SP2, and SP3, and may prevent gases that may be out-gassed from the color filters CF from moving to the light emitting device ED.

The first insulating layer 222 may be disposed in a region where the sub-pixels SP1, SP2, and SP3 are disposed and in a region between the sub-pixels SP1, SP2, and SP3. The first insulating layer 222 may be disposed continuously from the region where the sub-pixels SP1, SP2, and SP3 are disposed to the region between the sub-pixels SP1, SP2, and SP3. The first insulating layer 222 may include a flat top surface S11.

The second insulating layer 224 may include a plurality of insulating patterns with shapes that protrude from the first insulating layer 222 in opposite direction to the first substrate 111. Thus, the second insulating layer 224 may be expressed as an insulating pattern. Each second insulating pattern 224 is disposed to correspond to one of the sub-pixels SP1, SP2, and SP3, and may be spaced apart from each other. That is, the plurality of second insulating patterns 224 may not be disposed between the sub-pixels SP1, SP2, and SP3, and may expose a portion of the top surface S11 of the first insulating layer 222 between the sub-pixels SP1, SP2, and SP3.

Each second insulating pattern 224 has a shape that protrudes in opposite direction to the first substrate 111, and thus may include a top surface S21 and side surfaces S22 and S23 disposed on at least one side of the top surface S21. In one example, the second insulating pattern 224 may include a first side surface S22 disposed on a first side of the top surface S21 and a second side surface S23 disposed on a second side facing the first side of the top surface S21. As another example, the second insulating pattern 224 may be formed such that the top surface S21 corresponds to the shape of the sub-pixels SP1, SP2, and SP3, and may have side surface along the edges of the top surface S21.

The top surface S21 of the second insulating pattern 224 may be a flat surface. The side surfaces S22 an S23 of the second insulating pattern 224 may be sloped surfaces. The side surfaces S22 and S23 of the second insulating pattern 224 may have a high slope. In one example, the side surfaces S22 and S23 of the second insulating pattern 224 may have a slope greater than or equal to 70°. In the display panel 110 according to the first aspect of the present disclosure, the side surfaces S22 and S23 of the second insulating pattern 224 have a high slope, thereby reducing the separation distance between the sub-pixels SP1, SP2, and SP3.

The first insulating layer 222 and the second insulating layer (or second insulating pattern, 224) may be formed of an organic insulating material, such as acrylic resin, epoxy resin, phenolic resin, polyamide resin, polyimide resin, or the like.

The light emitting device ED may be disposed on the insulating layer 220. The light emitting device ED may be disposed in each of the sub-pixels SP1, SP2, and SP3. Each light emitting device ED may include a first electrode E1, a light emitting layer EL, and a second electrode E2.

The first electrode E1 may be disposed on the insulating layer 220. Specifically, the first electrode E1 may be disposed per sub-pixel SP1, SP2, and SP3 on the top surface S21 of the second insulating pattern 224. The first electrode E1 may also be disposed on the side surfaces S22 and S23 of the second insulating pattern 224 as shown in FIG. 5. The first electrode E1 may extend from the top surface S21 of the second insulating pattern 224 to the side surfaces S22 and S23 of the second insulating pattern 224. However, it is not necessarily limited thereto. The first electrode E1 may be disposed only on the top surface S21 of the second insulating pattern 224.

Further, the first electrode E1 may be connected with the driving transistor DT shown in FIG. 4. Specifically, the first electrode E1 may be connected to one of the source electrode and the drain electrode of the driving transistor DT shown in FIG. 4 through contact hole penetrating the insulating layer 220 and at least some of the plurality of insulating layers provided in the circuit element layer 210.

The first electrode E1 may include a transparent conductive material TCO such as ITO or IZO that may transmit light. The first electrode E1 may be an anode electrode of the light emitting device ED.

The light emitting layer EL may be disposed on the first electrode E1. The light emitting layer EL may include an emission material layer EML containing an emission material. The emission material may include an organic material, an inorganic material, or a hybrid material. The light emitting layer EL may have a multi-layer structure. For example, the light emitting layer EL may include at least one of a hole injection layer (HIL), a hole transport layer (HTL), an electron transport layer (ETL), and an electron injection layer (EIL). In this case, when a voltage is applied to the first electrode E1 and the second electrode E2, holes and electrons move to the emission material layer EML through the hole transport layer and the electron transport layer, respectively, and combine with each other in the emission material layer EML to emit light.

In one aspect, the light emitting layer EL may be a common layer commonly formed in the sub-pixels SP1, SP2, and SP3. In this case, the light emitting layer EL may be a white light emitting layer that emits white light. In this case, the light emitting layer EL may be formed not only on the sub-pixels SP1, SP2, and SP3 but also in the region between the sub-pixels SP1, SP2, and SP3. The light emitting layer EL may be formed continuously in the sub-pixels SP1, SP2, and SP3 and between the sub-pixels SP1, SP2, and SP3. The light emitting layer EL may be formed on the top surface S21 and the side surfaces S22 and S23 of the second insulating pattern 224 in the sub-pixels SP1, SP2, and SP3, and may be formed along the side surfaces S22 and S23 of the second insulating pattern 224.

In another aspect, the light emitting layer EL may be formed per sub-pixel SP1, SP2, and SP3. For example, a red light emitting layer emitting red light may be formed in the first sub-pixel SP1, a green light emitting layer emitting green light may be formed in the second sub-pixel SP2, and a blue light emitting layer emitting blue light may be formed in the third sub-pixel SP3. The light emitting layer EL disposed on each of the sub-pixels SP1, SP2, and SP3 may be formed on the top surface S21 of the second insulating pattern 224. Further, the light emitting layer EL disposed in each of the sub-pixels SP1, SP2, SP3 may be formed along the side surfaces S22 and S23 of the second insulating pattern 224 on the side surfaces S22 and S23 of the second insulating pattern 224. The light emitting layer EL may overlap all of the side surfaces S22 and S23 of the second insulating pattern 224, but is not necessarily limited thereto, and may overlap at least a portion of the side surfaces S22 and S23 of the second insulating pattern 224.

The second electrode E2 may be disposed on the light emitting layer EL. The second electrode E2 may be a common layer commonly formed in the sub-pixels SP1, SP2, and SP3. The second electrode E2 may be formed not only in the sub-pixels SP1, SP2, and SP3, but also in the region between the sub-pixels SP1, SP2, and SP3. The second electrode E2 may be formed continuously in the sub-pixels SP1, SP2, and SP3 and between the sub-pixels SP1, SP2, and SP3. The second electrode E2 may be formed on the top surface S21 and the side surfaces S22 and S23 of the second insulating pattern 224 in the sub-pixels SP1, SP2, and SP3, and may be formed along the side surfaces S22 and S23 of the second insulating pattern 224.

The second electrode E2 may include a conductive material having a high reflectivity. The second electrode E2 may include a metal such as aluminum Al, silver Ag, titanium Ti, or silver-palladium-copper APC alloy. The second electrode E2 may be a cathode electrode.

The display panel 110 according to the first aspect of the present disclosure may include a reflective layer 240 in the path of light emitted from the light emitting layer EL. The reflective layer 240 may be disposed on the side surfaces S22 and S23 of the second insulating pattern 224 to change the path of the light emitted from the light emitting layer EL to the front direction. Here, the front direction may indicate a direction toward the first substrate 111.

Specifically, some of the light L1 and L2 emitted from the light emitting layer EL may pass through the second insulating pattern 224 and be directed toward the side surfaces S22 and S23 of the second insulating pattern 224, as shown in FIG. 7. The light L1 and L2 directed to the side surfaces S22 and S23 of the second insulating pattern 224 may be reflected by the reflective layer 240. In this case, the reflection angle of the light L1 and L2 incident on the reflective layer 240 may vary depending on the angle of incidence. Accordingly, some of the light L1 reflected by the reflective layer 240 may pass between the plurality of metal patterns 215 disposed between the second insulating pattern 224 and the first substrate 111, and may be emitted to the outside through the first substrate 111. Meanwhile, another portion L2 of the light reflected by the reflective layer 240 may be reflected again by at least one of the plurality of metal patterns 215 and change its path toward the second substrate 112. The light L2 reflected by the metal patterns 215 may be reflected again by the second electrode E2 as shown in FIG. 7 and emitted to the outside through the first substrate 111.

As shown in FIG. 5, the reflective layer 240 may be disposed on the side surfaces S22 and S23 of the second insulating pattern 224, as well as on at least a portion of the top surface S21 of the second insulating pattern 224, but is not necessarily limited thereto. The reflective layer 240 may be disposed only on the side surfaces S22 and S23 of the second insulating pattern 224.

The reflective layer 240 may be disposed between the second insulating pattern 224 and the light emitting layer EL. Specifically, as shown in FIG. 5, when the first electrode E1 is disposed on the side surfaces S22 and S23 of the second insulating pattern 224, the reflective layer 240 may be disposed between the first electrode E1 disposed on the side surface S22 and S23 of the second insulating pattern 224 and the light emitting layer EL, but is not necessarily limited thereto. The first electrode E1 may also be disposed only on the top surface S21 of the second insulating pattern 224. In this case, the reflective layer 240 may be disposed between the side surfaces S22 and S23 of the second insulating pattern 224 and the light emitting layer EL.

At least a portion of the reflective layer 240 may overlap the first electrode E1. The reflective layer 240 may overlap at least a portion of the edge region (or peripheral region) of the first electrode E1. As shown in FIG. 6, the reflective layer 240 may be disposed along the edge region (or peripheral region) of the first electrode E1, overlapping the edge region (or peripheral region) of the first electrode E1.

The reflective layer 240 may be formed to directly contact the top surface of the first electrode E1 in a region overlapping the first electrode E1, and may be electrically connected to the first electrode E1. In this case, the reflective layer 240 may be an anode electrode of the light emitting device ED together with the first electrode E1.

In one aspect, the reflective layer 240 may be disposed so that entire surface of the reflective layer 240 is in contact with the first electrode E1, as shown in FIG. 5. In the display panel 110 according to the first aspect of the present disclosure, the first electrode E1 and the reflective layer 240 may be patterned through the same etching process to simplify the process. Through this, the reflective layer 240 may be disposed so that the entire surface of the reflective layer 240 is in contact with the first electrode E1, and one end of the reflective layer 240 may be disposed at the same position as the end of the first electrode E1.

The reflective layer 240 may be made of a single layer or may be made of a plurality of layers. The reflective layer 240 may be made of the single layer including reflective material. When the reflective layer 240 is made of the plurality of layers, one of the plurality of layers may include a reflective material.

In one aspect, as shown in FIG. 5, the reflective layer 240 may include a first layer 241 and a second layer 242 on the first layer 241. At least one of the first layer 241 and the second layer 242 may include a reflective material. The first layer 241 may include a reflective material and the second layer 242 may include a transparent material. The second layer 242 may include the same material as the first electrode E1, and may be formed with a thickness T2 that is thinner than the thickness T1 of the first electrode E1. Meanwhile, the first layer 241 and the second layer 242 of the reflective layer 240 may include a conductive material electrically connected to the first electrode E1.

In one example, the first layer 241 of the reflective layer 240 may include a metal such as aluminum Al, silver Ag, titanium Ti, or silver-palladium-copper APC alloy, which are conductive materials with high reflectivity. The second layer 242 of the reflective layer 240 may include a transparent conductive material TCO, such as ITO or IZO, which may transmit light.

The encapsulating layer 250 may be disposed on the light emitting device ED. The encapsulating layer 250 may prevent damage to the light emitting device ED due to external moisture and impact. The encapsulating layer 250 may have a multi-layer structure. For example, the encapsulating layer 250 may include at least one inorganic film and at least one organic film.

In the display panel 110 according to the first aspect of the present disclosure, the light emitting device ED may be disposed on a second insulating pattern 224 having a shape protruding in a direction opposite to the first substrate 111. The second insulating pattern 224 has a top surface S21 and side surfaces S22 and S23. The reflective layer 240, the light emitting layer EL, and the second electrode E2 may be stacked sequentially on the side surfaces S22 and S23 of the second insulating pattern 224.

In particular, in the display panel 110 according to the first aspect of the present disclosure, since the reflective layer 240 is disposed on the side surfaces S22 and S23 of the second insulating pattern 224, light L emitted from the light emitting device ED and moved to the side surfaces S22 and S23 of the second insulating pattern 224 may be reflected by the reflective layer 240, thereby changing path of the light in the front direction. Accordingly, the display panel 110 according to the first aspect of the present disclosure may improve light extraction efficiency.

Further, in the display panel 110 according to the first aspect of the present disclosure, the plurality of metal patterns 215 may be disposed between the first substrate 111 and the insulating layer 220. The plurality of metal patterns 215 may include an opaque metal material and may have a high reflectivity. The plurality of metal patterns 215 may overlap the second insulating pattern 224, as shown in FIG. 5, and may be disposed in a peripheral area rather than a central area to avoid obstructing the progression of light emitted from the light emitting layer EL and directed toward the front. The plurality of metal patterns 215 may overlap at least partially the side surfaces S22 and S23 of the second insulating pattern 224, and may overlap at least partially the reflective layer 240. When the first electrode E1 is also disposed on the side surfaces S22 and S23 of the second insulating pattern 224, the plurality of metal patterns 215 may overlap at least partially the first electrode E1.

In this case, as shown in FIG. 7, some of the light L2 reflected by the reflective layer 240 may be reflected again by at least one of the plurality of metal patterns 215 to change the light path toward the second substrate 112. The light L2 reflected by the metal patterns 215 may be reflected again by the second electrode E2 and emitted to the outside through the first substrate 111.

In the display panel 110 according to the first aspect of the present disclosure, by forming the reflective layer 240, a distance from a emission point at which light is emitted from the light emitting layer EL to a reflection point at which light that has passed through the second insulating pattern 224 is reflected by the reflective material may be minimized.

When the reflective layer 240 is not provided, the light emitted from the light emitting layer EL and directed toward the side surfaces S22 and S23 of the second insulating pattern 224 may be reflected by the second electrode E2. In this case, as the distance from the emission point to the reflection point increases, the angle of incidence when the light is incident on the metal pattern 215 may increase. Thus, as the angle of reflection also increases, the light may proceed to the adjacent sub-pixels SP1, SP2, and SP3, and thus, light leakage may occur.

Further, in the display panel 110, a bank may be disposed on the first electrode E1 to cover an end of the first electrode E1. In this case, the bank may be disposed to cover the side surfaces S22 and S23 of the second insulating pattern 224, and the second electrode E2 may be disposed on the bank. In the display panel 110 including the bank, the distance from the emission point to the reflection point becomes larger due to the bank, and the angle of incidence at which light is incident on the metal pattern 215 may also become larger. Accordingly, the display panel 110 including the bank may allow a large amount of light to proceed to the adjacent sub-pixels SP1, SP2, and SP3.

In the display panel 110 according to the first aspect of the present disclosure, since the reflective layer 240 is disposed on the side surfaces S22 and S23 of the second insulating pattern 224, the distance from the emission point to the reflection point of the light directed to the surfaces S22 and S23 of the second insulating pattern 224 may be minimized. In the display panel 110 according to the first aspect of the present disclosure, even if light is reflected by the metal pattern 215, the angle of incidence at which light is incident on the metal pattern 215 is small, so that the light may be emitted to the outside through the first substrate 111 without proceeding to the adjacent sub-pixels SP1, SP2, and SP3. Accordingly, the display panel 110 according to the first aspect of the present disclosure may prevent light leakage and prevent color mixing from occurring between adjacent sub-pixels SP1, SP2, and SP3.

Meanwhile, FIG. 5 illustrates that the plurality of metal patterns 215 overlap the second insulating pattern 224, but is not necessarily limited thereto. In a modified aspect, as shown in FIG. 8, the plurality of metal patterns 215 may not overlap the second insulating pattern 224. The plurality of metal patterns 215 may not overlap the first electrode E1 and the reflective layer 240, and may be disposed only in the region between the emission areas EA of the sub-pixels SP1, SP2, and SP3. In this case, the light L1 and L2 reflected by the reflective layer 240 is not reflected by the metal patterns 215, and most of it passes between the plurality of metal patterns 215 disposed between the first substrate 111 and the second insulating pattern 224, and may be emitted to the outside through the first substrate 111.

Light may be partially lost as it is reflected several times by components such as the metal patterns 215, the second electrode E2, and the reflective layer 240. The display panel 110 according to the modified aspect may be provided such that the metal patterns 215 do not overlap the second insulating pattern 224, thereby reducing the number of reflections of the light emitted from the light emitting layer EL until it is emitted to the outside. Accordingly, in the display panel 110 according to the modified aspect, light loss inside the display panel 110 may be reduced and light extraction efficiency may be improved. Furthermore, in the display panel 110 according to the modified aspect, since the light L1 and L2 reflected by the reflective layer 240 does not proceed to the adjacent sub-pixels SP1, SP2, and SP3, thereby preventing light leakage and color mixing.

Furthermore, in the display panel 110 according to the first aspect of the present disclosure, the reflective layer 240 may be electrically connected to the first electrode E1. Accordingly, in the display panel 110 according to the first aspect of the present disclosure, the light emitting layer EL may emit light even on the side surfaces S22 and S23 of the second insulating pattern 224 on which the reflective layer 240 is disposed.

Specifically, in the display panel 110 according to a first aspect of the present disclosure, the emission area EA may include a first emission area EA1 and a second emission area EA2. The first emission area EA1 may correspond to an area where the first electrode E1 is exposed without being covered by the reflective layer 240. The light emitting layer EL may be disposed to directly contact the first electrode E1 in the first emission area EA1, such that the light emitting layer EL may emit light between the first electrode E1 and the second electrode E2. This first emission area EA1 may overlap the top surface S21 of the second insulating pattern 224. Light emitted from the first emission area EA1 may be incident on the top surface S21 of the second insulating pattern 224. Some of the light emitted from the first light emission area EA1 may pass through the second insulating pattern 224 and the first insulating layer 222 and then may be emitted to the outside through the first substrate 111. As shown in FIG. 7, other portions L1 and L2 of the light emitted from the first emission area EA1 may be reflected by at least one of the reflective layer 240 disposed on the side surfaces S22 and S23 of the second insulating pattern 224, the second electrode E2, and the metal pattern 215, and then may be emitted to the outside through the first substrate 111.

The second emission area EA2 may correspond to the area with the reflective layer 240. The light emitting layer EL may be disposed to directly contact the reflective layer 240 in the second emission area EA2, so that the light emitting layer EL may emit light between the reflective layer 240 and the second electrode E2. The second emission area EA2 may overlap the side surfaces S22 and S23 of the second insulating pattern 224. As shown in FIG. 7, the light emitted from the second emission area EA2 may be incident on the top surface S11 of the first insulating layer 222 after repeated reflection between the reflective layer 240 and the second electrode E2. Subsequently, a portion of the light emitted from the second emission area EA2 may pass through the first insulating layer 222 and then may be emitted to the outside through the first substrate 111. Another portion L3 of the light emitted from the second emission area EA2 may be reflected by the metal pattern 215 and the second electrode E2 and then emitted to the outside through the first substrate 111.

In the display panel 110 according to the first aspect of the present disclosure, the emission area EA may include not only the first emission area EA1 but also the second emission area EA2. In the display panel 110 according to the first aspect of the present disclosure, the emission area EA may have a width W2 of the emission emitting area EA greater than the width W1 of the second insulating pattern 224, an area of the emission area EA may increase, and the light efficiency may be improved. Accordingly, the display panel 110 according to the first aspect of the present disclosure may have a high light extraction efficiency with low power, and may further reduce power consumption.

Furthermore, the display panel 110 according to the first aspect of the present disclosure may reduce the separation distance between the sub-pixels SP1, SP2, and SP3 by forming the side surfaces S22 and S23 of the second insulating pattern 224 to have a high slope. The display panel 110 according to the first aspect of the present disclosure may reduce an area of the non-emission area NEA and improve the aperture ratio.

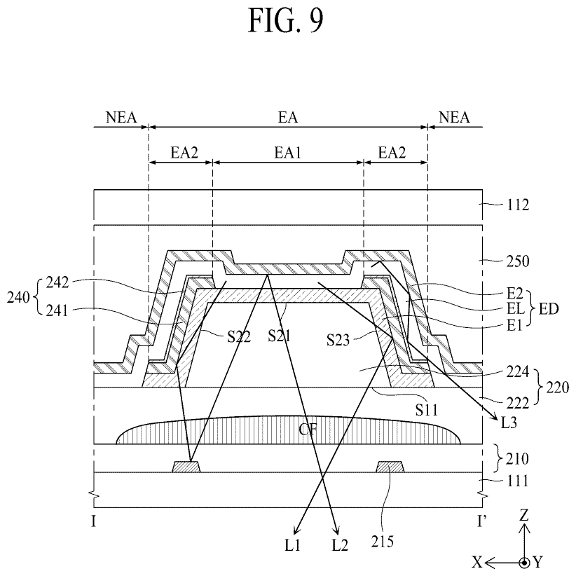

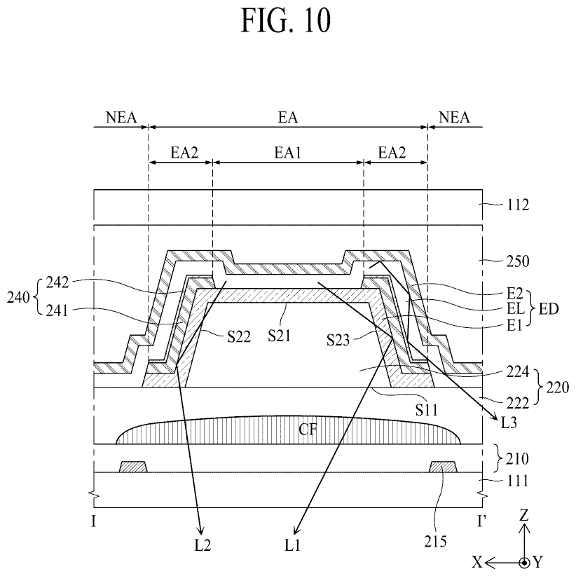

FIG. 9 is a cross-sectional view illustrating a second example of the sub-pixel taken along line to I-I′ shown in FIG. 3 according to one or more aspects of the present disclosure, FIG. 10 is a cross-sectional view illustrating a modified example of the sub-pixel shown in FIG. 9 according to one or more aspects of the present disclosure.

The display panel 110 shown in FIG. 9 is different from the display panel 110 shown in FIG. 5 only in the first electrode E1 and the reflective layer 240, and the remaining components are substantially the same. Thus, detailed description of the remaining components will be omitted.

Referring to FIG. 9, the display panel 110 according to a second aspect of the present disclosure includes a first substrate 111 and a second substrate 112 facing each other. A circuit element layer 210, a color filter CF, an insulating layer 220, a light emitting device ED, a reflective layer 240, and an encapsulating layer 250 may be disposed between the first substrate 111 and the second substrate 112.

The light emitting device ED may be disposed on the insulating layer 220. The light emitting device ED may be disposed in each of the sub-pixels SP1, SP2, and SP3. Each of the light emitting device ED may include a first electrode E1, a light emitting layer EL, and a second electrode E2.

The first electrode E1 may be disposed on the insulating layer 220. Specifically, the first electrode E1 may be disposed per sub-pixel SP1, SP2, and SP3 on the top surface S21 of the second insulating pattern 224. The first electrode E1 may also be disposed on the side surfaces S22 and S23 of the second insulating pattern 224 and on at least a portion of the top surface of the S11 first insulating layer 222, as shown in FIG. 9. The first insulating layer 222 may be exposed between the sub-pixels SP1, SP2, and SP3 without being covered by the second insulating pattern 224. The first electrode E1 may extend from the top surface S21 of the second insulating pattern 224 through the side surfaces S22 and S23 of the second insulating pattern 224 to at least a portion of the top surface S11 of the first insulating layer 222 that is exposed without being covered by the second insulating pattern 224. However, it is not necessarily limited thereto. The first electrode E1 may be disposed only on the top surface S21 of the second insulating pattern 224.

The reflective layer 240 may be disposed on the side surfaces S22 and S23 of the second insulating pattern 224 to change the path of light emitted from the light emitting layer EL in the front direction. Here, the front direction may refer to a direction toward the first substrate 111.

Specifically, some of the light L1 and L2 emitted from the light emitting layer EL may pass through the second insulating pattern 224 and be directed toward the side surfaces S22 and S23 of the second insulating pattern 224, as shown in FIG. 9. The light L1 and L2 directed to the side surfaces S22 and S23 of the second insulating pattern 224 may be reflected by the reflective layer 240. In this case, the reflection angle of the light L1 and L2 incident on the reflective layer 240 may vary depending on the angle of incidence. Accordingly, some of the light L1 reflected by the reflective layer 240 may pass between the plurality of metal patterns 215 disposed between the second insulating pattern 224 and the first substrate 111, and may be emitted to the outside through the first substrate 111. Meanwhile, another portion L2 of the light reflected by the reflective layer 240 may be reflected again by at least one of the plurality of metal patterns 215 and change its path toward the second substrate 112. The light L2 reflected by the metal patterns 215 may be reflected again by the second electrode E2 as shown in FIG. 9 and emitted to the outside through the first substrate 111.

As shown in FIG. 9, the reflective layer 240 may be disposed on at least a portion of the top surface S21 of the first insulating layer 222, as well as on the side surfaces S22 and S23 of the second insulating pattern 224. The first insulating layer 222 may be exposed without being covered by the second insulating pattern 224 between the sub-pixels SP1, SP2, and SP3. The reflective layer 240 may extend from the side surfaces S22 and S23 of the second insulating pattern 224 to at least a portion of the top surface S11 of the first insulating layer 222 that is exposed without being covered by the second insulating pattern 224.

Furthermore, the reflective layer 240 may be disposed on at least a portion of the top surface S11 of the first insulating layer 222, as well as on the side surfaces S22 and S23 of the second insulating pattern 224 and on at least a portion of the top surface S21 of the first insulating layer 222, but is not necessarily limited thereto. The reflective layer 240 may be disposed only on the side surfaces S22 and S23 of the second insulating pattern 224 and on at least a portion of the top surface S11 of the first insulating layer 222.

The reflective layer 240 may be disposed between the second insulating pattern 224 and the light emitting layer EL. Specifically, as shown in FIG. 9, when the first electrode E1 is disposed on the side surfaces S22 and S23 of the second insulating pattern 224, the reflective layer 240 may be disposed between the first electrode E1 disposed on the side surface S22 and S23 of the second insulating pattern 224 and the light emitting layer EL, but is not necessarily limited thereto. The first electrode E1 may also be disposed only on the top surface S21 of the second insulating pattern 224. In this case, the reflective layer 240 may be disposed between the side surfaces S22 and S23 of the second insulating pattern 224 and the light emitting layer EL.

At least a portion of the reflective layer 240 may overlap the first electrode E1. The reflective layer 240 may overlap at least a portion of the edge region (or peripheral region) of the first electrode E1. The reflective layer 240 may be disposed along the edge region (or peripheral region) of the first electrode E1, overlapping the edge region (or peripheral region) of the first electrode E1.

The reflective layer 240 may be formed to directly contact the top surface of the first electrode E1 in a region overlapping the first electrode E1, and may be electrically connected to the first electrode E1. In this case, the reflective layer 240 may be an anode electrode of the light emitting device ED together with the first electrode E1.

In one aspect, the reflective layer 240 may be disposed so that entire surface of the reflective layer 240 is in contact with the first electrode E1, as shown in FIG. 9. In the display panel 110 according to the second aspect of the present disclosure, the first electrode E1 and the reflective layer 240 may be patterned through the same etching process to simplify the process. Through this, the reflective layer 240 may be disposed so that the entire surface of the reflective layer 240 is in contact with the first electrode E1, and one end of the reflective layer 240 may be disposed at the same position as the end of the first electrode E1.

The reflective layer 240 may be made of a single layer or may be made of a plurality of layers. The reflective layer 240 may be made of the single layer including reflective material. When the reflective layer 240 is made of the plurality of layers, one of the plurality of layers may include a reflective material.

In one aspect, as shown in FIG. 9, the reflective layer 240 may include a first layer 241 and a second layer 242 on the first layer 241. At least one of the first layer 241 and the second layer 242 may include a reflective material. The first layer 241 may include a reflective material and the second layer 242 may include a transparent material. The second layer 242 may include the same material as the first electrode E1, and may be formed with a thickness that is thinner than the thickness of the first electrode E1. Meanwhile, the first layer 241 and the second layer 242 of the reflective layer 240 may include a conductive material electrically connected to the first electrode E1.

In one example, the first layer 241 of the reflective layer 240 may include a metal such as aluminum Al, silver Ag, titanium Ti, or silver-palladium-copper APC alloy, which are conductive materials with high reflectivity. The second layer 242 of the reflective layer 240 may include a transparent conductive material TCO, such as ITO or IZO, which may transmit light.

In the display panel 110 according to the second aspect of the present disclosure, since the reflective layer 240 is disposed on the side surfaces S22 and S23 of the second insulating pattern 224, the light L emitted from the light emitting device ED and moved to the side surfaces S22 and S23 of the second insulating pattern 224 may be reflected by the reflective layer 240, thereby changing path of the light in the front direction. Accordingly, the display panel 110 according to the second aspect of the present disclosure may improve light extraction efficiency.

Further, in the display panel 110 according to the second aspect of the present disclosure, the plurality of metal patterns 215 may be disposed between the first substrate 111 and the insulating layer 220. The plurality of metal patterns 215 may include an opaque metal material and may have a high reflectivity. The plurality of metal patterns 215 may overlap the second insulating pattern 224, as shown in FIG. 9, and may be disposed in a peripheral area rather than a central area to avoid obstructing the progression of light emitted from the light emitting layer EL and directed toward the front. The plurality of metal patterns 215 may overlap at least partially the side surfaces S22 and S23 of the second insulating pattern 224, and may overlap at least partially the reflective layer 240. When the first electrode E1 is also disposed on the side surfaces S22 and S23 of the second insulating pattern 224, the plurality of metal patterns 215 may overlap at least partially the first electrode E1.

In this case, as shown in FIG. 9, some of the light L2 reflected by the reflective layer 240 may be reflected again by at least one of the plurality of metal patterns 215 to change the light path toward the second substrate 112. The light L2 reflected by the metal patterns 215 may be reflected again by the second electrode E2 and emitted to the outside through the first substrate 111.

In the display panel 110 according to the second aspect of the present disclosure, by forming the reflective layer 240, a distance from an emission point at which light is emitted from the light emitting layer EL to a reflection point at which light that has passed through the second insulating pattern 224 is reflected by the reflective material may be minimized. In the display panel 110 according to the second aspect of the present disclosure, even if light is reflected by the metal pattern 215, the angle of incidence at which light is incident on the metal pattern 215 is small, so that the light may be emitted to the outside through the first substrate 111 without proceeding to the adjacent sub-pixels SP1, SP2, and SP3. Accordingly, the display panel 110 according to the second aspect of the present disclosure may prevent light leakage and prevent color mixing from occurring between adjacent sub-pixels SP1, SP2, and SP3.

Meanwhile, FIG. 9 illustrates that the plurality of metal patterns 215 overlap the second insulating pattern 224, but is not necessarily limited thereto. In a modified aspect, as shown in FIG. 10, the plurality of metal patterns 215 may not overlap the second insulating pattern 224. The plurality of metal patterns 215 may not overlap the first electrode E1 and the reflective layer 240, and may be disposed only in the region between the emission areas EA of the sub-pixels SP1, SP2, and SP3. In this case, the light L1 and L2 reflected by the reflective layer 240 is not reflected by the metal patterns 215, and most of it passes between the plurality of metal patterns 215 disposed between the first substrate 111 and the second insulating pattern 224, and may be emitted to the outside through the first substrate 111.

Light may be partially lost as it is reflected several times by components such as the metal patterns 215, the second electrode E2, and the reflective layer 240. The display panel 110 according to the modified aspect may be provided such that the metal patterns 215 do not overlap the second insulating pattern 224, thereby reducing the number of reflections of the light emitted from the light emitting layer EL until it is emitted to the outside. Accordingly, in the display panel 110 according to the modified aspect, light loss inside the display panel 110 may be reduced and light extraction efficiency may be improved. Furthermore, in the display panel 110 according to the modified aspect, since the light L1 and L2 reflected by the reflective layer 240 does not proceed to the adjacent sub-pixels SP1, SP2, and SP3, thereby preventing light leakage and color mixing.

Furthermore, in the display panel 110 according to the second aspect of the present disclosure, the reflective layer 240 may be electrically connected to the first electrode E1. Accordingly, in the display panel 110 according to the second aspect of the present disclosure, the light emitting layer EL may emit light even on the top surface S11 of the first insulating layer 222 and on the side surfaces S22 and S23 of the second insulating pattern 224 on which the reflective layer 240 is disposed.

Specifically, in the display panel 110 according to a second aspect of the present disclosure, the emission area EA may include a first emission area EA1 and a second emission area EA2. The first emission area EA1 may correspond to an area where the first electrode E1 is exposed without being covered by the reflective layer 240. The light emitting layer EL may be disposed to directly contact the first electrode E1 in the first emission area EA1, such that the light emitting layer EL may emit light between the first electrode E1 and the second electrode E2. This first emission area EA1 may overlap the top surface S21 of the second insulating pattern 224. Light emitted from the first emission area EA1 may be incident on the top surface S21 of the second insulating pattern 224. Some of the light emitted from the first light emission area EA1 may pass through the second insulating pattern 224 and the first insulating layer 222, and then may be emitted to the outside through the first substrate 111. As shown in FIG. 9, other portions L1 and L2 of the light emitted from the first emission area EA1 may be reflected by at least one of the reflective layer 240 disposed on the side surfaces S22 and S23 of the second insulating pattern 224, the second electrode E2, and the metal pattern 215, and then may be emitted to the outside through the first substrate 111.

The second emission area EA2 may correspond to the area with the reflective layer 240. The light emitting layer EL may be disposed to directly contact the reflective layer 240 in the second emission area EA2, so that the light emitting layer EL may emit light between the reflective layer 240 and the second electrode E2. The second emission area EA2 may overlap the side surfaces S22 and S23 of the second insulating pattern 224 and at least a portion of the top surface S11 of the first insulating layer 222 that is exposed without being covered by the second insulating pattern 224. As shown in FIG. 9, the light emitted L3 from the second emission area EA2 may be incident on the top surface S11 of the first insulating layer 222 after repeated reflection between the reflective layer 240 and the second electrode E2. Subsequently, the light L3 emitted from the second emission area EA2 may pass through the first insulating layer 222 and then may be emitted to the outside through the first substrate 111.

In the display panel 110 according to the second aspect of the present disclosure, since the emission area EA may include not only the first emission area EA1 but also the second emission area EA2, an area of the emission area EA may increase. Furthermore, in the display panel 110 according to the second aspect of the present disclosure, since the reflective layer 240 may extend not only to the side surfaces S22 and S23 of the second insulating pattern 224, but also to at least a portion of the top surface S11 of the first insulating layer 222 that is exposed without being covered by the second insulating pattern 224, the area of the second emissive area EA2 may be increased, and thus, then area of the emission area EA may be maximized and light efficiency may be significantly improved. Accordingly, the display panel 110 according to the second aspect of the present disclosure may have a high light extraction efficiency with low power, and may further reduce power consumption.

Furthermore, in the display panel 110 according to the second aspect of the present disclosure, since the reflective layer 240 may be extended to at least a portion of the top surface S11 of the first insulating layer 222 that is exposed without being covered by the second insulating pattern 224, the range in which light emitted from the emission area EA is emitted may be increased. Accordingly, in the display panel 110 according to the second aspect of the present disclosure, the viewing angle may be widened.

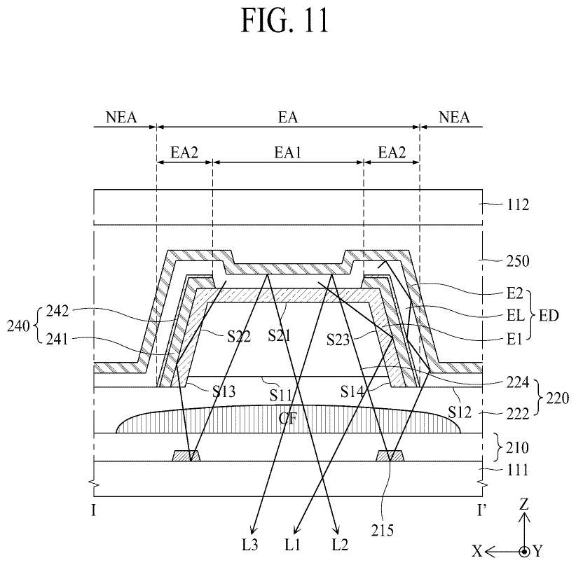

FIG. 11 is a cross-sectional view illustrating a third example of the sub-pixel taken along line I-I′ shown in FIG. 3 according to one or more aspects of the present disclosure.

The display panel 110 shown in FIG. 11 is different from the display panel 110 shown in FIG. 5 only in the first electrode E1 and the reflective layer 240, and the remaining components are substantially the same. Thus, detailed description of the remaining components will be omitted.

Referring to FIG. 11, the display panel 110 according to a third aspect of the present disclosure includes a first substrate 111 and a second substrate 112 facing each other. A circuit element layer 210, a color filter CF, an insulating layer 220, a light emitting device ED, a reflective layer 240, and an encapsulating layer 250 may be disposed between the first substrate 111 and the second substrate 112.

The insulating layer 220 may be disposed on the color filter CF. The insulating layer 220 may include two insulating layers 222 and 224 with different refractive indices to improve the extraction efficiency of light emitted from the light emitting device ED. The insulating layer 220 may include a first insulating layer 222 and a second insulating layer 224.

The first insulating layer 222 is disposed on the color filter CF and may have a first refractive index. The second insulating layer 224 is disposed on the first insulating layer 222 and may have a second refractive index. In one example, the second refractive index may be greater than the first refractive index.

The first insulating layer 222 may be disposed on the color filter CF to cover the color filter CF. The second insulating layer 224 may include a plurality of insulating patterns with shapes that protrude from the first insulating layer 222 in opposite direction to the first substrate 111. Thus, the second insulating layer 224 may be expressed as an insulating pattern.

The first insulating layer 222 may be disposed in the region where the second insulating pattern 224 are disposed and in the region between the second insulating pattern 224. A height of the first insulating layer 222 in the region where the second insulating pattern 224 are disposed may be different from a height of the first insulating layer 222 in the region between the second insulating pattern 224. In detail, the first insulating layer 222 may include a first top surface S11 disposed in the region where the second insulating pattern 224 are disposed, a second top surface S12 disposed in the region between the second insulating pattern 224, and a side surfaces S13 and S14 connecting the first top surface S11 and the second top surface S12. A separation distance between the second top surface S12 and the first substrate 111 is shorter than a separation distance between the first top surface S11 and the first substrate 111. The first top surface S11 and the second top surface S12 of the first insulating layer 222 may be flat surfaces, and the side surfaces S13 and S14 of the first insulating layer 222 may be a sloped surface.

Each of the plurality of second insulating pattern 224 is disposed to correspond to each of the sub-pixels SP1, SP2, and SP3, and may be spaced apart from each other. That is, the plurality of second insulating pattern 224 may not be disposed between the sub-pixels SP1, SP2, and SP3, and may expose the second top surface S12 of the first insulating layer 222 between the sub-pixels SP1, SP2, and SP3.

Each of the plurality of second insulating patterns 224 has a shape that protrudes in opposite direction to the first substrate 111, and thus may include a top surface S21 and side surfaces S22 and S23 disposed on at least one side of the top surface S21. In one example, the second insulating pattern 224 may include a first side surface S22 disposed on a first side of the top surface S21 and a second side surface S23 disposed on a second side facing the first side of the top surface S21. As another example, the second insulating pattern 224 may be formed such that the top surface S21 corresponds to the shape of the sub-pixels SP1, SP2, and SP3, and may have side surface along the edges of the top surface S21.

The top surface S21 of the second insulating pattern 224 may be a flat surface. The side surfaces S22 an S23 of the second insulating pattern 224 may be sloped surfaces. The side surfaces S22 and S23 of the second insulating pattern 224 may form a single sloped surface with the side surfaces S13 and S14 of the first insulating layer 222. The sloped surface formed by the side surfaces S22 and S23 of the second insulating pattern 224 and the side surfaces S13 and S14 of the first insulating layer 222 may have a high slope. In one example, the sloped surface formed by the side surfaces S22 and S23 of the second insulating pattern 224 and the side surfaces S13 and S14 of the first insulating layer 222 may have a slope greater than or equal to 70°. In the display panel 110 according to the third aspect of the present disclosure, the sloped surface formed by the side surfaces S22 and S23 of the second insulating pattern 224 and the side surfaces S13 and S14 of the first insulating layer 222 may have a high slope, thereby reducing the separation distance between the sub-pixels SP1, SP2, and SP3.

The first insulating layer 222 and the second insulating layer (or insulating pattern, 224) may be formed of an organic insulating material, such as acrylic resin, epoxy resin, phenolic resin, polyamide resin, polyimide resin, or the like.

The light emitting device ED may be disposed on the insulating layer 220. The light emitting device ED may be disposed in each of the sub-pixels SP1, SP2, and SP3. Each of the light emitting device ED may include a first electrode E1, a light emitting layer EL, and a second electrode E2.

The first electrode E1 may be disposed on the insulating layer 220. Specifically, the first electrode E1 may be disposed per sub-pixel SP1, SP2, and SP3 on the top surface S21 of the second insulating pattern 224. The first electrode E1 may also be disposed on the side surfaces S22 and S23 of the second insulating pattern 224 and the side surfaces S13 and S14 of the first insulating layer 222, as shown in FIG. 11. The first electrode E1 may extend from the top surface S21 of the second insulating pattern 224, through the side surfaces S22 and S23 of the second insulating pattern 224, to the side surfaces S13 and S14 of the first insulating layer 222. However, it is not necessarily limited thereto. The first electrode E1 may be disposed only on the top surface S21 of the second insulating pattern 224.

The reflective layer 240 may be disposed on the side surfaces S22 and S23 of the second insulating pattern 224 and on the side surfaces S13 and S14 of the first insulating layer 222 to change the path of the light emitted from the light emitting layer EL to the front direction. Here, the front direction may indicate a direction toward the first substrate 111.

Specifically, some of the light L1 emitted from the light emitting layer EL may pass through the second insulating pattern 224 and be directed toward the side surfaces S22 and S23 of the second insulating pattern 224 or toward the side surfaces S13 and S14 of the first insulating layer 222. The light L1 directed to the side surfaces S22 and S23 of the second insulating pattern 224 or to the side surfaces S13 and S14 of the first insulating layer 222 may be reflected by the reflective layer 240. In this case, the reflection angle of the light L1 incident on the reflective layer 240 may vary depending on the angle of incidence. Accordingly, some of the light L1 reflected by the reflective layer 240 may pass between the plurality of metal patterns 215 disposed between the second insulating pattern 224 and the first substrate 111, and may be emitted to the outside through the first substrate 111. Meanwhile, another portion L2 of the light reflected by the reflective layer 240 may be reflected again by at least one of the plurality of metal patterns 215 and change its path toward the second substrate 112. The light L2 reflected by the metal patterns 215 may be reflected again by the second electrode E2 and emitted to the outside through the first substrate 111.

The reflective layer 240 may be disposed on at least a portion of the top surface S21 of the second insulating pattern 224, as well as on the side surfaces S22 and S23 of the second insulating pattern 224 and on the side surfaces S13 and S14 of the first insulating layer 222, but is not necessarily limited thereto. The reflective layer 240 may be disposed only on the side surfaces S22 and S23 of the second insulating pattern 224 and on the side surfaces S13 and S14 of the first insulating layer 222.

The reflective layer 240 may be disposed between the second insulating pattern 224 and the light emitting layer EL. Specifically, as shown in FIG. 11, when the first electrode E1 is disposed on the side surfaces S22 and S23 of the second insulating pattern 224 and on the side surfaces S13 and S14 of the first insulating layer 222, the reflective layer 240 may be disposed between the first electrode E1 and the light emitting layer EL, on the side surface S22 and S23 of the second insulating pattern 224 and on the side surfaces S13 and S14 of the first insulating layer 222, but is not necessarily limited thereto. The first electrode E1 may also be disposed only on the top surface S21 of the second insulating pattern 224. In this case, the reflective layer 240 may be disposed between the side surfaces S22 and S23 of the second insulating pattern 224 and the light emitting layer EL, and between the side surfaces S13 and S14 of the first insulating layer 222 and the light emitting layer EL.

At least a portion of the reflective layer 240 may overlap the first electrode E1. The reflective layer 240 may overlap at least a portion of the edge region (or peripheral region) of the first electrode E1. The reflective layer 240 may be disposed along the edge region (or peripheral region) of the first electrode E1, overlapping the edge region (or peripheral region) of the first electrode E1.

The reflective layer 240 may be formed to directly contact the top surface of the first electrode E1 in a region overlapping the first electrode E1, and may be electrically connected to the first electrode E1. In this case, the reflective layer 240 may be an anode electrode of the light emitting device ED together with the first electrode E1.

In one aspect, the reflective layer 240 may be disposed so that entire surface of the reflective layer 240 is in contact with the first electrode E1, as shown in FIG. 11. In the display panel 110 according to the third aspect of the present disclosure, the first electrode E1 and the reflective layer 240 may be patterned through the same etching process to simplify the process. Through this, the reflective layer 240 may be disposed so that the entire surface of the reflective layer 240 is in contact with the first electrode E1, and one end of the reflective layer 240 may be disposed at the same position as the end of the first electrode E1.

The reflective layer 240 may be made of a single layer or may be made of a plurality of layers. The reflective layer 240 may be made of the single layer including reflective material. When the reflective layer 240 is made of the plurality of layers, one of the plurality of layers may include a reflective material.

In one aspect, as shown in FIG. 11, the reflective layer 240 may include a first layer 241 and a second layer 242 on the first layer 241. At least one of the first layer 241 and the second layer 242 may include a reflective material. The first layer 241 may include a reflective material and the second layer 242 may include a transparent material. The second layer 242 may include the same material as the first electrode E1, and may be formed with a thickness that is thinner than the thickness of the first electrode E1. Meanwhile, the first layer 241 and the second layer 242 of the reflective layer 240 may include a conductive material electrically connected to the first electrode E1.

In one example, the first layer 241 of the reflective layer 240 may include a metal such as aluminum Al, silver Ag, titanium Ti, or silver-palladium-copper APC alloy, which are conductive materials with high reflectivity. The second layer 242 of the reflective layer 240 may include a transparent conductive material TCO, such as ITO or IZO, which may transmit light.

In the display panel 110 according to the third aspect of the present disclosure, since the reflective layer 240 is disposed on the side surfaces S22 and S23 of the second insulating pattern 224 and on the side surfaces S13 and S14 of the first insulating layer 222, light L1, L2, and L3 emitted from the light emitting device ED and moved to the side surfaces S22 and S23 of the second insulating pattern 224 or to the side surfaces S13 and S14 of the first insulating layer 222 may be reflected by the reflective layer 240, thereby changing path of the light in the front direction. Accordingly, the display panel 110 according to the third aspect of the present disclosure may improve light extraction efficiency.

Furthermore, in the display panel 110 according to the third aspect of the present disclosure, the reflective layer 240 may be electrically connected to the first electrode E1. Accordingly, in the display panel 110 according to the third aspect of the present disclosure, the light emitting layer EL may even emit light on the side surfaces S22 and S23 of the second insulating pattern 224 on which the reflective layer 240 is disposed and on the side surfaces S13 and S14 of the first insulating layer 222.

Specifically, in the display panel 110 according to a third aspect of the present disclosure, the emission area EA may include a first emission area EA1 and a second emission area EA2. The first emission area EA1 may correspond to an area where the first electrode E1 is exposed without being covered by the reflective layer 240. The light emitting layer EL may be disposed to directly contact the first electrode E1 in the first emission area EA1, such that the light emitting layer EL may emit light between the first electrode E1 and the second electrode E2. This first emission area EA1 may overlap the top surface S21 of the second insulating pattern 224. Light emitted from the first emission area EA1 may be incident on the top surface S21 of the second insulating pattern 224. Some of the light L1 emitted from the first light emission area EA1 may pass through the second insulating pattern 224 and the first insulating layer 222 and then may be emitted to the outside through the first substrate 111. Other portions L2 of the light emitted from the first emission area EA1 may be reflected by at least one of the reflective layer 240 disposed on the side surfaces S22 and S23 of the second insulating pattern 224 and on the side surfaces S13 and S14 of the first insulating layer 222, the second electrode E2, and the metal pattern 215, and then emitted to the outside through the first substrate 111.

The second emission area EA2 may correspond to the area with the reflective layer 240. The light emitting layer EL may be disposed to directly contact the reflective layer 240 in the second emission area EA2, so that the light emitting layer EL may emit light between the reflective layer 240 and the second electrode E2. The second emission area EA2 may overlap the side surfaces S22 and S23 of the second insulating pattern 224 and the side surfaces S13 and S14 of the first insulating layer 222. The light emitted L3 from the second emission area EA2 may be incident on the top surface S12 of the first insulating layer 222 after repeated reflection between the reflective layer 240 and the second electrode E2. Subsequently, the light L3 emitted from the second emission area EA2 may pass through the first insulating layer 222 and may be emitted to the outside through the first substrate 111 after reflected by the metal pattern 215 and the second electrode E2, or may pass through the first insulating layer 222 and then may be emitted to the outside through the first substrate 111.

In the display panel 110 according to the third aspect of the present disclosure, since the emission area EA may include not only the first emission area EA1 but also the second emission area EA2, an area of the emission area EA may increase. Furthermore, in the display panel 110 according to the third aspect of the present disclosure, since the reflective layer 240 may extend not only to the side surfaces S22 and S23 of the second insulating pattern 224, but also to at least a portion of the side surfaces S13 and S14 of the first insulating layer 222, the area of the second emissive area EA2 may be increased, and thus, then area of the emission area EA may be maximized and light efficiency may be significantly improved. Accordingly, the display panel 110 according to the third aspect of the present disclosure may have a high light extraction efficiency with low power, and may further reduce power consumption.

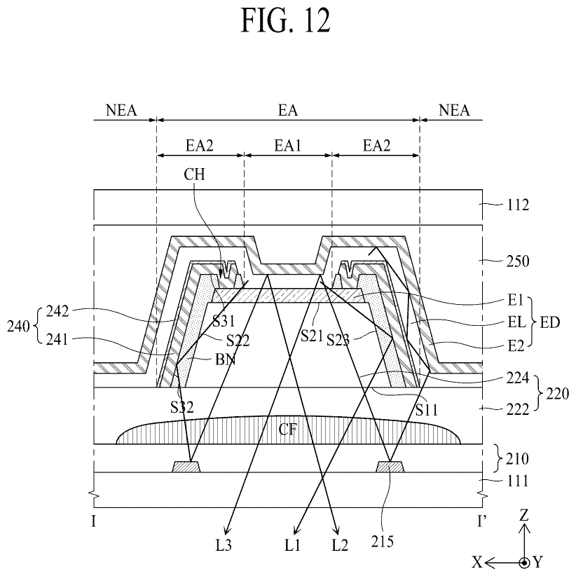

FIG. 12 is a cross-sectional view illustrating a fourth aspect of the sub-pixel taken along line I-I′ shown in FIG. 3 according to one or more aspects of the present disclosure.

The display panel 110 shown in FIG. 12 is different from the display panel 110 shown in FIG. 5 in that a bank BN is further disposed, and in the first electrode E1 and the reflective layer 240, and the remaining components are substantially the same. Thus, detailed description of the remaining components will be omitted.

Referring to FIG. 12, the display panel 110 according to a fourth aspect of the present disclosure includes a first substrate 111 and a second substrate 112 facing each other. A circuit element layer 210, a color filter CF, an insulating layer 220, a light emitting device ED, a reflective layer 240, and an encapsulating layer 250 may be disposed between the first substrate 111 and the second substrate 112.

The light emitting device ED may be disposed on the insulating layer 220. The light emitting device ED may be disposed in each of the sub-pixels SP1, SP2, and SP3. Each of the light emitting device ED may include a first electrode E1, a light emitting layer EL, and a second electrode E2.

The first electrode E1 may be disposed on the insulating layer 220. Specifically, the first electrode E1 may be disposed per sub-pixel SP1, SP2, and SP3 on the top surface S21 of the second insulating pattern 224.

The display panel 110 according to a fourth aspect of the present disclosure may further include a bank BN on the first electrode E1 of the light emitting device ED to cover an edge of the first electrode E1. The bank BN may include an opening through which the first electrode E1 is exposed to define a first emission area EA1. The light emitting layer EL of the light emitting device ED and the second electrode E2 may be stacked on the first electrode E1 exposed by the opening of the bank BN.

The bank BN may be disposed to cover the side surfaces S22 and S23 of the second insulating pattern 224 as shown in FIG. 12. The bank BN may include a top surface S31 and a side surface S32 provided along the side surfaces S22 and S23 of the second insulating pattern 224. However, it is not necessarily limited thereto. The banks BN may be provided only on the top surface S21 of the second insulating pattern 224.

The bank BN may include organic insulating materials and may have a single-layer or double-layer structure.

The reflective layer 240 may be disposed on the side surfaces S22 and S23 of the second insulating pattern 224 to change the path of light emitted from the light emitting layer EL in the front direction. Here, the front direction may refer to a direction toward the first substrate 111. When the bank BN is formed to cover the side surfaces S22 and S23 of the second insulating pattern 224, the reflective layer 240 may be disposed on the side surface S32 of the bank BN.

Some of the light L1 emitted from the light emitting layer EL may pass through the second insulating pattern 224 and be directed toward the side surfaces S22 and S23 of the second insulating pattern 224 and toward the side surface S32 of the bank BN. The light L1 directed to the side surfaces S22 and S23 of the second insulating pattern 224 and to the side surface S32 of the bank BN may be reflected by the reflective layer 240. In this case, the reflection angle of the light L1 incident on the reflective layer 240 may vary depending on the angle of incidence. Accordingly, some of the light L1 reflected by the reflective layer 240 may pass between the plurality of metal patterns 215 disposed between the second insulating pattern 224 and the first substrate 111, and may be emitted to the outside through the first substrate 111. Meanwhile, another portion L2 of the light reflected by the reflective layer 240 may be reflected again by at least one of the plurality of metal patterns 215 and change its path toward the second substrate 112. The light L2 reflected by the metal patterns 215 may be reflected again by the second electrode E2 and emitted to the outside through the first substrate 111. The reflective layer 240 may be disposed not only on the side surface S32 of the bank BN, but also on at least a portion of the top surface S31 of the bank BN.

The reflective layer 240 may be disposed between the second insulating pattern 224 and the light emitting layer EL. Specifically, as shown in FIG. 12, the reflective layer 240 may be disposed between the bank BN and the light emitting layer EL.

At least a portion of the reflective layer 240 may overlap the first electrode E1. The reflective layer 240 may overlap at least a portion of the edge region (or peripheral region) of the first electrode E1. The reflective layer 240 may be disposed along the edge region (or peripheral region) of the first electrode E1, overlapping the edge region (or peripheral region) of the first electrode E1.

The reflective layer 240 may be connected to the first electrode E1 via a contact hole CH through the bank BN in a region overlapping the first electrode E1, and thus may be electrically connected to the first electrode E1. In this case, the reflective layer 240 may be an anode electrode of the light emitting device ED together with the first electrode E1.

The reflective layer 240 may be made of a single layer or may be made of a plurality of layers. The reflective layer 240 may be made of the single layer including reflective material. When the reflective layer 240 is made of the plurality of layers, one of the plurality of layers may include a reflective material.

In one aspect, as shown in FIG. 12, the reflective layer 240 may include a first layer 241 and a second layer 242 on the first layer 241. At least one of the first layer 241 and the second layer 242 may include a reflective material. The first layer 241 may include a reflective material and the second layer 242 may include a transparent material. The second layer 242 may include the same material as the first electrode E1, and may be formed with a thickness that is thinner than the thickness of the first electrode E1. Meanwhile, the first layer 241 and the second layer 242 of the reflective layer 240 may include a conductive material electrically connected to the first electrode E1.

In one example, the first layer 241 of the reflective layer 240 may include a metal such as aluminum Al, silver Ag, titanium Ti, or silver-palladium-copper APC alloy, which are conductive materials with high reflectivity. The second layer 242 of the reflective layer 240 may include a transparent conductive material TCO, such as ITO or IZO, which may transmit light.

In the display panel 110 according to the fourth aspect of the present disclosure, since the reflective layer 240 is disposed on the side surfaces S22 and S23 of the second insulating pattern 224, the light L1, L2, and L3 emitted from the light emitting device ED and moved to the side surfaces S22 and S23 of the second insulating pattern 224 may be reflected by the reflective layer 240, thereby changing path of the light in the front direction. Accordingly, the display panel 110 according to the fourth aspect of the present disclosure may improve light extraction efficiency.

Further, in the display panel 110 according to the fourth aspect of the present disclosure, the reflective layer 240 may be electrically connected to the first electrode E1. Accordingly, in the display panel 110 according to the fourth aspect of the present disclosure, the light emitting layer EL may emit light even on the side surfaces S22 and S23 of the second insulating pattern 224 on which the reflective layer 240 is disposed.

Specifically, in the display panel 110 according to a fourth aspect of the present disclosure, the emission area EA may include a first emission area EA1 and a second emission area EA2. The first emission area EA1 may correspond to an area where the first electrode E1 is exposed without being covered by the bank BN. The light emitting layer EL may be disposed to directly contact the first electrode E1 in the first emission area EA1, such that the light emitting layer EL may emit light between the first electrode E1 and the second electrode E2. This first emission area EA1 may overlap the top surface S21 of the second insulating pattern 224. Light emitted from the first emission area EA1 may be incident on the top surface S21 of the second insulating pattern 224. Some of the light L1 emitted from the first light emission area EA1 may pass through the second insulating pattern 224 and the bank BN, and then may be emitted to the outside through the first substrate 111. Other portions L2 of the light emitted from the first emission area EA1 may be reflected by at least one of the reflective layer 240 disposed on the side surface S32 of the bank BN, the second electrode E2, and the metal pattern 215, and then emitted to the outside through the first substrate 111.

The second emission area EA2 may correspond to the area with the reflective layer 240. The light emitting layer EL may be disposed to directly contact the reflective layer 240 in the second emission area EA2, so that the light emitting layer EL may emit light between the reflective layer 240 and the second electrode E2. The second emission area EA2 may overlap the side surfaces S22 and S23 of the second insulating pattern 224 and the side surface S32 of the bank BN. The light emitted L3 from the second emission area EA2 may be incident on the top surface S12 of the first insulating layer 222 after repeated reflection between the reflective layer 240 and the second electrode E2. Subsequently, the light L3 emitted from the second emission area EA2 may pass through the first insulating layer 222 and may be emitted to the outside through the first substrate 111 after reflected by the metal pattern 215 and the second electrode E2, or may pass through the first insulating layer 222 and then may be emitted to the outside through the first substrate 111.

In the display panel 110 according to the fourth aspect of the present disclosure, since the emission area EA may include not only the first emission area EA1 but also the second emission area EA2, an area of the emission area EA may increase. Furthermore, in the display panel 110 according to the fourth aspect of the present disclosure, the bank BN with predetermined thicknesses may be disposed along the side surfaces S22 and S23 of the second insulating pattern 224 on the second insulating pattern 224, and reflective layer 240 may be disposed on the bank BN. Since the area of the side surface S32 of the bank BN is larger than the area of the side surfaces S22 and S23 of the second insulating pattern 224, in the display panel 110 according to the fourth aspect of the present disclosure, an area on which the reflective layer 240 is disposed may be increased, and thus, then area of the emission area EA may be maximized and light efficiency may be significantly improved. Accordingly, the display panel 110 according to the fourth aspect of the present disclosure may have a high light extraction efficiency with low power, and may further reduce power consumption.

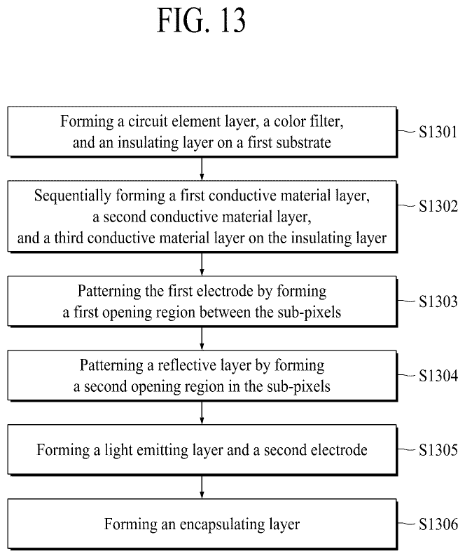

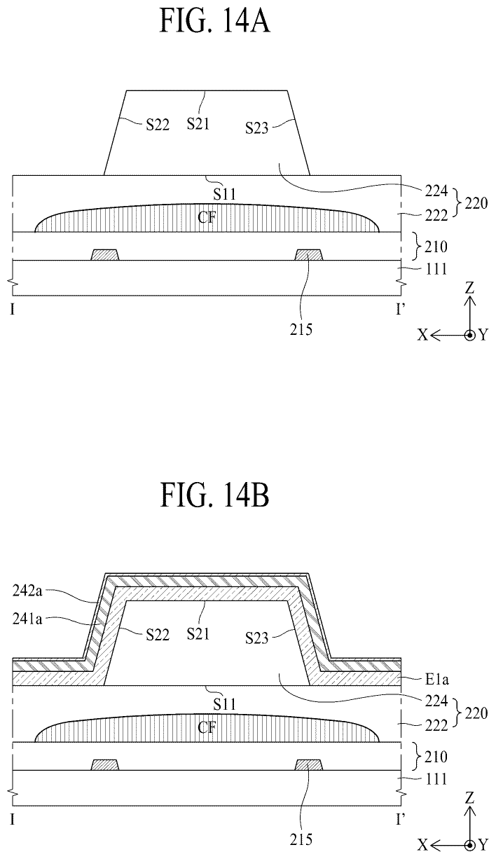

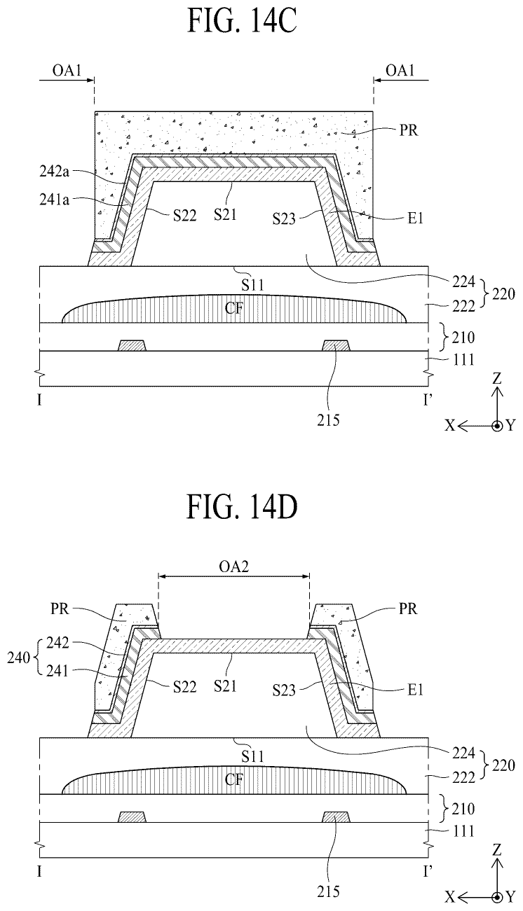

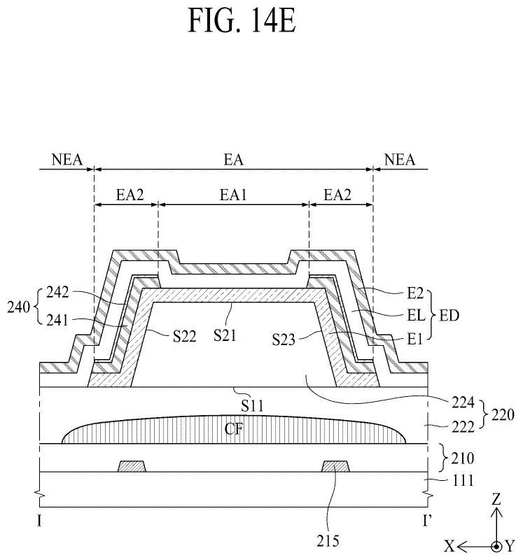

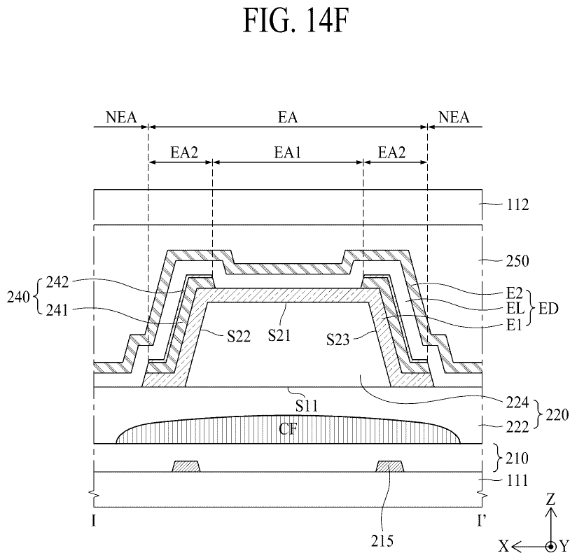

FIG. 13 is a flow chart illustrating a method of manufacturing a display panel according to one or more aspects of the present disclosure, FIGS. 14A to 14F are cross-sectional views illustrating a method of manufacturing a display panel according to one or more aspects of the present disclosure.

First, as shown in FIG. 14A, in the step S1301, a circuit element layer 210, a color filter CF, and an insulating layer 220 are formed on the first substrate 111.

Specifically, the circuit element layer 210 may be formed on the first substrate 111. The circuit element layer 210 is provided with circuit elements including various signal lines, thin-film transistor, capacitor, and the like for each of the subpixels SP1, SP2, and SP3.

Then, the color filter CF may be patterned on the circuit element layer 210 for each of the sub-pixels SP1, SP2, and SP3. The first color filter may be formed at a position corresponding to the emission area EA of the first sub-pixel SP1. In one example, the first color filter may be a red color filter that transmits red light. A second color filter may be formed at a position corresponding to the emission area EA of the second sub-pixel SP2. In one example, the second color filter may be a green color filter that transmits green light. A third color filter may be formed at a position corresponding to the emission area EA of the third sub-pixel SP3. In one example, the third color filter may be a blue color filter that transmits blue light. When the pixel further includes a fourth sub-pixel, a fourth color filter may be formed at a position corresponding to the emission area EA of the fourth sub-pixel. In one example, the fourth color filter may be a white color filter that transmits white light, and the white color filter may be made of a transparent organic material that transmits white light.

Then, a first insulating layer 222 may be formed on the color filter CF. The first insulating layer 222 may be formed to cover the color filter CF. The first insulating layer 222 may be formed of an organic insulating material such as acrylic resin, epoxy resin, phenolic resin, polyamide resin, polyimide resin, or the like.

Then, an insulating material layer may be formed to form second insulating pattern 224 on the first insulating layer 222. The insulating material layer may be formed of an organic insulating material, such as an acrylic resin, epoxy resin, phenolic resin, polyamide resin, polyimide resin, or the like. The insulating material layer may be formed a different material than that of the first insulating layer 222.

Then, the insulating material layer may be etched in the region between the sub-pixels SP1, SP2, and SP3 to form the second insulating pattern 224. The second insulating pattern 224 is formed to correspond to each of the sub-pixels SP1, SP2, and SP3 and may be spaced apart from each other. The second insulating patterns 224 may expose a portion of the top surface S11 of the first insulating layer 222 between the sub-pixels SP1, SP2, and SP3.

Each of the second insulating patterns 224 may have a shape that protrudes in the opposite direction to the first substrate 111 and may include a top surface S21, and side surfaces S22 and S23 disposed on at least one side of the top surface S21.

Next, in the step S1302, a first conductive material layer E1a, a second conductive material layer 241a, and a third conductive material layer 242a are sequentially formed on the insulating layer 220.

Specifically, as shown in FIG. 14B, a first conductive material layer E1a may be formed on the insulating layer 220. The first conductive material layer E1a may be formed on the top surface S21 of the second insulating pattern 224, the side surfaces S22 and S23 of the second insulating pattern 224, and the top surface S11 of the first insulating layer 222 that is exposed without being covered by the second insulating pattern 224. The first conductive material layer E1a may include a transparent conductive material TCO such as ITO, IZO, or other transparent metal material that may transmit light.

Then, the second conductive material layer 241a may be formed on the first conductive material layer E1a. The second conductive material layer 241a may include metal such as aluminum Al, silver Ag, titanium Ti, and silver-palladium-copper APC alloys, which are conductive materials with high reflectivity.

Then, the third conductive material layer 242a may be formed on the second conductive material layer 241a. The third conductive material layer 242a may include a transparent conductive material TCO such as ITO or IZO that may transmit light. The third conductive material layer 242a may be made of the same material as the first conductive material layer E1a, and may be formed with a thickness that is thinner than the thickness of the first conductive material layer E1a.

Next, in the step S1303, the first electrode E1 is patterned by forming a first opening region OA1 in each of the first conductive material layer E1a, the second conductive material layer 241a, and the third conductive material layer 242a between the sub-pixels SP1, SP2, and SP3.

More specifically, as shown in FIG. 14C, a photoresist pattern PR may be formed on the third conductive material layer 242a. The photoresist pattern PR may be formed at a location where each of the sub-pixels SP1, SP2, and SP3 are to be formed. The second conductive material layer 241a and the third conductive material layer 242a not covered by the photoresist pattern PR may be etched using the first etchant. The first etchant may be determined depending on the material comprising the second conductive material layer 241a. The third conductive material layer 242a may have a thin thickness, e.g., 100 Å, to be easily etched by the first etchant. The first conductive material layer E1a may remain without being etched by the first etchant.

Then, the first conductive material layer E1a not covered by the photoresist pattern PR may be etched using a second etchant. The second etchant may be determined depending on the material comprising the first conductive material layer E1a and may be different from the first etchant. The first conductive material layer E1a may be made of the same material as the third conductive material layer 242a, but may have a thicker thickness than the third conductive material layer 242a, for example, 1000 Å or more.

As a result, a first opening region OA1 may be formed in each of the first conductive material layer E1a, the second conductive material layer 241a, and the third conductive material layer 242a. The first conductive material layer E1a having the first opening region OA1 may be patterned in each of the sub-pixels SP1, SP2, and SP3. The patterned first conductive material layer E1a may be the first electrode E1.

Next, in the step S1304, the reflective layer 240 is patterned by forming a second opening area OA2 in each of the second conductive material layer 241a and third conductive material layer 242a in the sub-pixels SP1, SP2, and SP3.

More specifically, as shown in FIG. 14D, a portion of the photoresist pattern PR may be removed. The photoresist pattern PR may remain in a location corresponding to the sides surfaces S22 and S23 of the second insulating pattern 224.

Then, the second conductive material layer 241a and the third conductive material layer 242a, which are not covered by the photoresist pattern PR, may be etched using the first etchant. The first conductive material layer E1a may remain without being etched by the first etchant.

Then, the photoresist pattern (PR) may be removed.

As a result, the second opening area OA2 may be formed in each of the second conductive material layer 241a and the third conductive material layer 242a. The second conductive material layer 241a and the third conductive material layer 242a having the first opening region OA1 and the second opening region OA2 may be patterned at locations corresponding to the side surfaces S22 and S23 of the second insulating pattern 224. The patterned second conductive material layer 241a and the patterned third conductive material layer 242a may be the first layer 241 and the second layer 242 of the reflective layer 240, respectively.

Next, in the step S1305, the light emitting layer EL and the second electrode E2 are formed sequentially on the first electrode E1 and the reflective layer 240.

More specifically, as shown in FIG. 14E, the light emitting layer EL may be formed on the first electrode E1 and the reflective layer 240. The light emitting layer EL may be formed by a deposition process or a solution process. The light emitting layer EL may be a white light emitting layer that emits white light. In this case, the light emitting layer EL may be a common layer commonly formed in the sub-pixels SP1, SP2, and SP3.

Then, the second electrode E2 may be formed on the light emitting layer EL. The second electrode E2 may be a common layer commonly formed in the sub-pixels SP1, SP2, and SP3. The second electrode E2 may include a metal such as aluminum Al, silver Ag, titanium Ti, or silver-palladium-copper APC alloy, which are a conductive material with highly reflective.

Next, in the step S1306, an encapsulation layer 250 is formed on the second electrode E2.

More specifically, as shown in FIG. 14F, the encapsulation layer 250 including at least one inorganic film and at least one organic film may be formed on the second electrode E2.

Then, the second substrate 112 may be attached to the encapsulation layer 250.

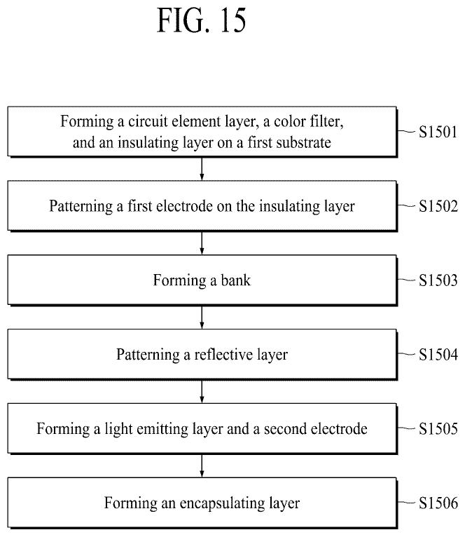

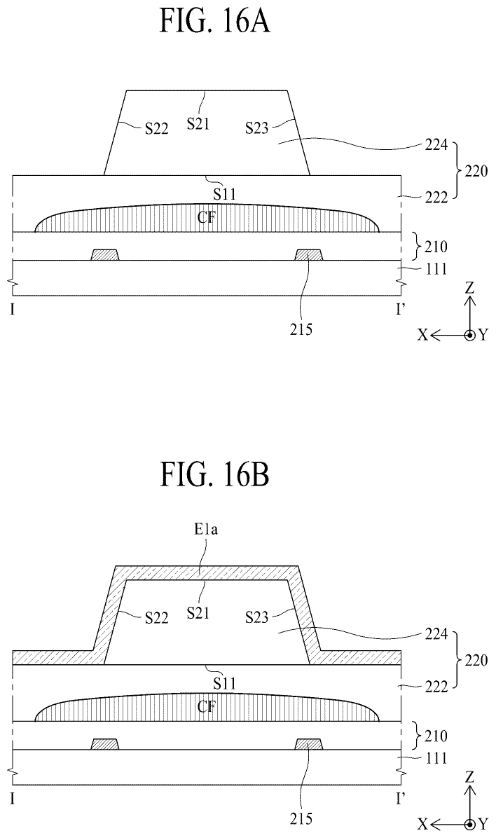

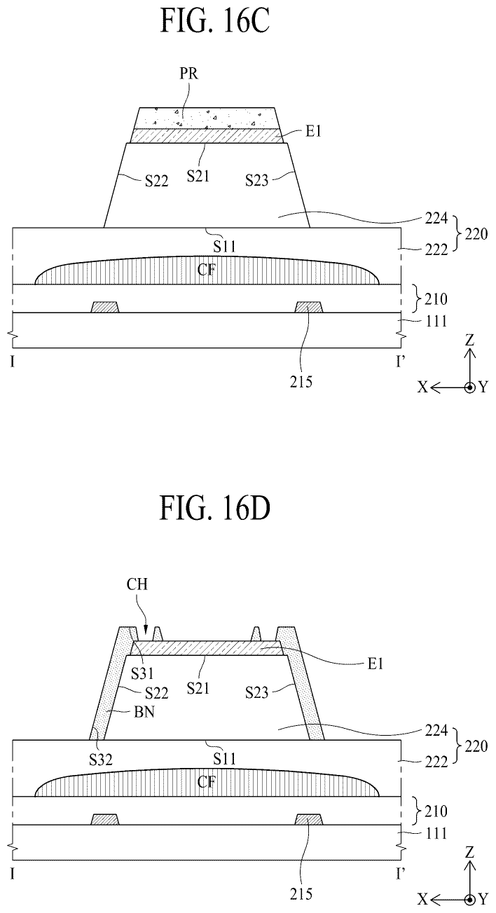

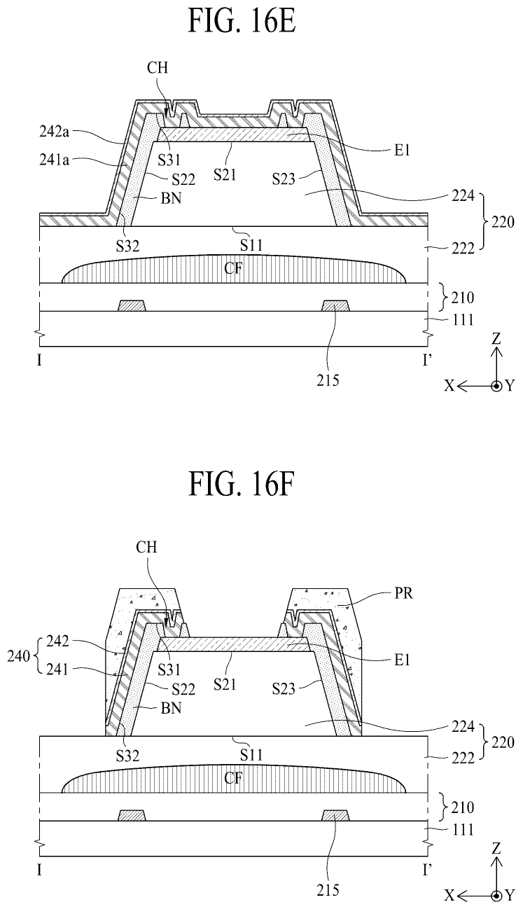

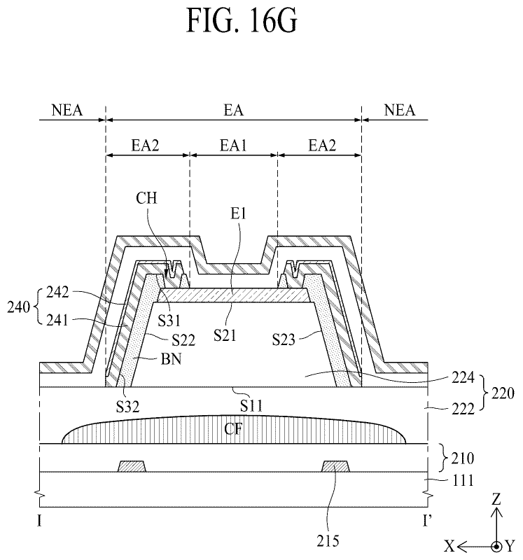

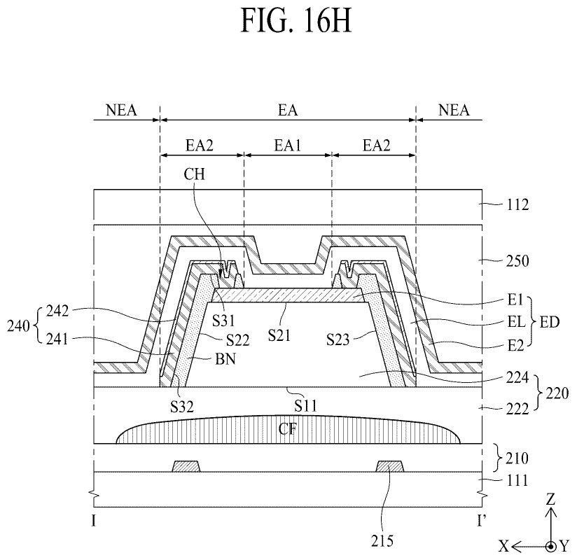

FIG. 15 is a flow chart illustrating a method of manufacturing a display panel according to one or more aspects of the present disclosure, and FIGS. 16A to 16H are cross-sectional views illustrating a method of manufacturing a display panel according to one or more aspects of the present disclosure.

First, in the step S1501, a circuit element layer 210, a color filter CF, and an insulating layer 220 are formed on the first substrate 111.

Specifically, as shown in FIG. 16A, the circuit element layer 210 may be formed on the first substrate 111. The circuit element layer 210 is provided with circuit elements including various signal lines, thin-film transistor, capacitor, and the like for each of the subpixels SP1, SP2, and SP3.

Then, the color filter CF may be patterned on the circuit element layer 210 for each of the sub-pixels SP1, SP2, and SP3. The first color filter may be formed at a position corresponding to the emission area EA of the first sub-pixel SP1. In one example, the first color filter may be a red color filter that transmits red light. A second color filter may be formed at a position corresponding to the emission area EA of the second sub-pixel SP2. In one example, the second color filter may be a green color filter that transmits green light. A third color filter may be formed at a position corresponding to the emission area EA of the third sub-pixel SP3. In one example, the third color filter may be a blue color filter that transmits blue light. When the pixel further includes a fourth sub-pixel, a fourth color filter may be formed at a position corresponding to the emission area EA of the fourth sub-pixel. In one example, the fourth color filter may be a white color filter that transmits white light, and the white color filter may be made of a transparent organic material that transmits white light.

Then, a first insulating layer 222 may be formed on the color filter CF. The first insulating layer 222 may be formed to cover the color filter CF. The first insulating layer 222 may be formed of an organic insulating material such as acrylic resin, epoxy resin, phenolic resin, polyamide resin, polyimide resin, or the like.

Then, an insulating material layer may be formed to form second insulating pattern 224 on the first insulating layer 222. The insulating material layer may be formed of an organic insulating material, such as acrylic resin, epoxy resin, phenolic resin, polyamide resin, polyimide resin, or the like. The insulating material layer may be formed a different material than that of the first insulating layer 222.

Then, the insulating material layer may be etched in the region between the sub-pixels SP1, SP2, and SP3 to form the second insulating pattern 224. The second insulating pattern 224 is formed to correspond to each of the sub-pixels SP1, SP2, and SP3 and may be spaced apart from each other. The second insulating patterns 224 may expose a portion of the top surface S11 of the first insulating layer 222 between the sub-pixels SP1, SP2, and SP3.

Each of the second insulating patterns 224 may have a shape that protrudes in the opposite direction to the first substrate 111 and may include a top surface S21, and side surfaces S22 and S23 disposed on at least one side of the top surface S21.

Next, in the step S1502, the first electrode E1 is patterned on the insulating layer 220.

Specifically, as shown in FIG. 16B, a first conductive material layer E1a may be formed on the insulating layer 220. The first conductive material layer E1a may be formed on the top surface S21 of the second insulating pattern 224, the side surfaces S22 and S23 of the second insulating pattern 224, and on the top surface S11 of the first insulating layer 222 that is exposed without being covered by the second insulating pattern 224. The first conductive material layer E1a may include a transparent conductive material TCO such as ITO, IZO, or other transparent metal material that may transmit light.

Then, as shown in FIG. 16C, a photoresist pattern PR may be formed on the first conductive material layer E1a. The photoresist pattern PR may be formed at a location where each of the sub-pixels SP1, SP2, and SP3 are to be formed. The first conductive material layer E1a not covered by the photoresist pattern PR may be etched using the second etchant. The second etchant may be determined depending on the material forming the first conductive material layer E1a. The second etchant may be different from the first etchant.

As a result, the first conductive material layer may be patterned in each of the sub-pixels SP1, SP2, and SP3. The patterned first conductive material layer E1a may be the first electrode E1.

Then, the photoresist pattern PR may be removed.

Next, in the step S1503, the bank BN may be formed at an edge region of the first electrode E1.

Specifically, as shown in FIG. 16D, the bank BN may be formed on the first electrode E1 to cover the edge of the first electrode E1. The bank BN may comprise an opening through which a portion of the first electrode E1 is exposed. In this case, the opening may correspond to the first emission region EA1. Further, the bank BN may comprise contact holes CH penetrating the bank BN for contact with the reflective layer 240 to be deposited later.

The bank BN may be formed to cover the side surfaces S22 and S23 of the second insulating pattern 224. The bank BN may include a top surface S31 and a side surface S32 provided along the side surfaces S22 and S23 of the second insulating pattern 224. The bank BN may include an organic insulating material.

Next, in the step S1504, the reflective layer 240 is patterned on the bank BN.

Specifically, as shown in FIG. 16E, a second conductive material layer 241a may be formed on the first electrode E1, the bank BN, and the insulating layer 220. The second conductive material layer 241a may include a metal such as aluminum Al, silver Ag, titanium Ti, and silver-palladium-copper APC alloys, which are conductive materials with high reflectivity.

Then, a third conductive material layer 242a may be formed on the second conductive material layer 241a. The third conductive material layer 242a may include a transparent conductive material TCO, such as ITO or IZO, that may transmit light. The third conductive material layer 242a may be made of the same material as the first electrode E1, and may be formed to have a thickness thinner than that of the first electrode E1.

Then, as shown in FIG. 16F, a photoresist pattern PR may be formed on the third conductive material layer 242a. The photoresist pattern PR may be formed at positions corresponding to the bank BN or the side surfaces S22 and S23 of the second insulating pattern 224.

Then, the second conductive material layer 241a and the third conductive material layer 242a, which are not covered by the photoresist pattern PR, may be etched using the first etchant. The first etchant may be determined depending on the material forming the second conductive material layer 241a. The third conductive material layer 242a may have a thin thickness, e.g., 100 Å, to be easily etched by the first etchant. The first conductive material layer E1a may remain without being etched by the first etchant.

As a result, each of the second conductive material layer 241a and the third conductive material layer 242a may be patterned at positions corresponding to the bank BN or the side surfaces S22 and S23 of second insulating pattern 224. The patterned second conductive material layer 241a and third conductive material layer 242a may be the first layer 241 and second layer 242 of the reflective layer 240, respectively.

The first layer 241 of the reflective layer 240 may be electrically connected to the first electrode E1 through the contact hole CH provided in the bank BN.

Next, in the step S1505, the light emitting layer EL and the second electrode E2 are formed sequentially on the first electrode E1 and the reflective layer 240.

More specifically, as shown in FIG. 16G, the light emitting layer EL may be formed on the first electrode E1 and the reflective layer 240. The light emitting layer EL may be formed by a deposition process or a solution process. The light emitting layer EL may be a white light emitting layer that emits white light. In this case, the light emitting layer EL may be a common layer commonly formed in the sub-pixels SP1, SP2, and SP3.

Then, the second electrode E2 may be formed on the light emitting layer EL. The second electrode E2 may be a common layer commonly formed in the sub-pixels SP1, SP2, and SP3. The second electrode E2 may include a metal such as aluminum Al, silver Ag, titanium Ti, or silver-palladium-copper APC alloy, which are conductive materials with highly reflective.

Next, in the step S1506, an encapsulation layer 250 is formed on the second electrode E2.

More specifically, as shown in FIG. 16H, the encapsulation layer 250 including at least one inorganic film and at least one organic film may be formed on the second electrode E2.

Then, the second substrate 112 may be attached to the encapsulation layer 250.

In the present disclosure, since the reflective layer is disposed on the side surface of the insulating pattern, the path of the light emitted from the light emitting device and moving to the side surface of the insulating pattern may be changed to a front direction using the reflective layer, thereby improving light extraction efficiency.

Moreover, in the present disclosure, by minimizing the distance from the emission point where the light is emitted to the reflection point where the light is reflected by the reflective layer, the light may be emitted outwardly through the first substrate without proceeding to the adjacent sub-pixel even if the light is reflected by the metal pattern. Accordingly, in the present disclosure, light leakage may be prevented and color mixing between adjacent sub-pixels may be prevented.

Moreover, in the present disclosure, since the reflective layer is electrically connected to the first electrode, the light emitting layer may emit light even on the side surface of the insulating pattern on which the reflective layer is disposed. Accordingly, in the present disclosure, an area of an emission area may be increased, a high light extraction efficiency may be obtained even with low power, and further, power consumption may be reduced.

Embodiments of the present disclosure have been described in more detail with reference to the accompanying drawings, but the present disclosure is not necessarily limited to these embodiments and may be modified in various ways without departing from the technical sprit of the present disclosure. Accordingly, the embodiments disclosed herein are intended to illustrate and not to limit the technical sprit of the present disclosure, and the scope of the technical sprit of the present disclosure is not limited by these embodiments. Therefore, it should be understood that the above-described embodiments are exemplary in all respects and not limited. The scope of protection of the present disclosure shall be construed by the claims, and all technical sprit within the equivalent scope of the claims should be construed to be included within the scope of the present disclosure.

Claim language or other language reciting “at least one of” a set and/or “one or more” of a set indicates that one member of the set or multiple members of the set (in any combination) satisfy the claim. For example, claim language reciting “at least one of A and B” or “at least one of A or B” means A, B, or A and B. In another example, claim language reciting “at least one of A, B, and C” or “at least one of A, B, or C” means A, B, C, or A and B, or A and C, or B and C, or A and B and C. The language “at least one of” a set and/or “one or more” of a set does not limit the set to the items listed in the set. For example, claim language reciting “at least one of A and B” or “at least one of A or B” can mean A, B, or A and B, and can additionally include items not listed in the set of A and B.

1. A display panel comprising:
a plurality of sub-pixels, each of the plurality of sub-pixels including:
a substrate;
a first insulating layer on the substrate and protruding away from the substrate, the first insulating layer having two side surfaces; and
a light emitting device on the first insulating layer having a first electrode, a second electrode, and a light emitting layer, the first electrode at least partially covering the first insulating layer, wherein the second electrode is on the two side surfaces.

2. The display panel of claim 1, further comprising:
a reflective layer including a first layer on the first electrode and a second layer on the first layer, the first layer being formed of reflective material and the second layer being formed of transparent material.

3. The display panel of claim 2, wherein a thickness of the second layer is smaller than a thickness of the first electrode.

4. The display panel of claim 1, further comprising:
a second insulating layer, wherein the first insulating layer has a first refractive index and the second insulating layer has a second refractive index.

5. The display panel of claim 4, wherein the first refractive index is greater than the second refractive index.

6. The display panel of claim 1, further comprising:
a circuit element layer including a plurality of metal patterns.

7. The display panel of claim 6, further comprising:
a color filter on the circuit element layer covering the plurality of metal patterns.

8. The display panel of claim 7, wherein the color filter corresponds to an emission area of a corresponding one of the plurality of sub-pixels.

9. The display panel of claim 1, wherein the two side surfaces are inclined.

10. The display panel of claim 2, wherein the first layer contacts and covers the two side surfaces while partially covering a top surface of the first insulating layer.

11. The display panel of claim 1, wherein the light emitting layer has a multi-layer structure.

12. The display panel of claim 1, wherein the first electrode extends horizontally beyond the two side surfaces and partially covering a top surface of a second insulating layer, the first insulating layer being on the second insulating layer.

13. The display panel of claim 6, wherein the plurality of metal patterns are in a non-emission area between two adjacent ones of the plurality of sub-pixels and do not overlap with the first insulating layer and the first electrode.

14. The display panel of claim 1, wherein the first insulating layer is on a second insulating layer, the second insulating layer extending beyond a horizontal length of the first insulating layer to cover non-emission areas between adjacent ones of the plurality of sub-pixels.

15. The display panel of claim 14, wherein the second insulating layer has a first height from a top surface of the substrate in a first region and a second height from the top surface of the substrate in a second region.

16. The display panel of claim 15, wherein the first region is where the second insulating layer contacts the first insulating layer and the second region is where the second insulating layer covers the non-emission areas.

17. The display panel of claim 2, wherein the first electrode is horizontally disposed on a top surface of the first insulating layer.

18. The display panel of claim 17, further comprising:
a bank layer disposed between the first layer and each of the two side surfaces.

19. The display panel of claim 18, wherein the first layer covers the bank layer and a portion of the first electrode.

20. The display panel of claim 19, wherein the first layer contacts the portion of the first electrode through the bank layer via a contact hole.

21. The display panel of claim 1, wherein each of the plurality of sub-pixels has an emission area including a first emission area and two side emission areas, the two side emission areas corresponding to the two side surfaces.

22. The display panel of claim 21, wherein light is directly emitted in the first emission area.

23. The display panel of claim 21, wherein the light is emitted both directly and via reflection in the two side emission areas.
